(19) United States
(12) Patent Application Publication
(10) Pub. No.: US 2026/0352072 A1
(43) Pub. Date: Nov. 5, 2026

(54) ELECTRIC WORK MACHINE, AND METHOD FOR CONTROLLING BRUSHLESS MOTOR IN ELECTRIC WORK MACHINE

(71) Applicant: MAKITA CORPORATION, Anjo-shi (JP)

(72) Inventors: Shu ISAKA, Anjo-shi (JP); Yuki MATSUMOTO, Anjo-shi (JP); Shin TSUJITA, Anjo-shi (JP); Yuya MATSUYAMA, Anjo-shi (JP)

(73) Assignee: MAKITA CORPORATION, Anjo-shi (JP)

(21) Appl. No.: 19/653,234

(22) Filed: Apr. 21, 2026

(30) Foreign Application Priority Data
Apr. 30, 2025 (JP) 2025-075592

(51) Int. Cl. H02K 11/33; G01R 31/389; G01R 31/396; H02K 7/14; H02K 19/10; H02P 21/00; H02P 21/22

(52) U.S. Cl. CPC H02K 11/33; G01R 31/389; G01R 31/396; H02K 7/145; H02K 19/10; H02P 21/0021; H02P 21/22; H02P 2207/05

(57) ABSTRACT

One aspect of the present disclosure provides an electric work machine including a brushless motor, a drive circuit, and a control circuit. The control circuit selectively sets an operation mode of the electric work machine to one of a first mode and a second mode. The control circuit controls the brushless motor according to a first control scheme in the first mode. The control circuit controls the brushless motor according to a second control scheme in the second mode. The first control scheme (i) is a control scheme other than field-oriented control or (ii) includes a first field-oriented control. The second control scheme includes a second field-oriented control. The first field-oriented control is different from the second field-oriented control.

### CROSS-REFERENCE TO RELATED APPLICATIONS

This application claims the benefit of Japanese Patent Application No. 2025-075592 filed on Apr. 30, 2025 with the Japan Patent Office, the entire disclosure of which is incorporated herein by reference.

### BACKGROUND

The present disclosure relates to a technology for controlling a brushless motor in an electric work machine.

Japanese Unexamined Patent Application Publication No. 2023-31617 discloses an electric work machine equipped with a brushless motor. This electric work machine is configured such that square-wave voltages are applied to the brushless motor to thereby drive the brushless motor.

### SUMMARY

In the electric work machine, the brushless motor is driven by the square-wave voltages, and thus enables the brushless motor to achieve higher rotational speeds. However, from the viewpoint of control performance and so on (e.g., control stability and/or control accuracy), there may be cases where an operable range (e.g., a maximum value of an output torque in a low-speed range) may be limited. In this case, the output torque of the brushless motor may be insufficient in practical work. For example, in a situation in which the brushless motor is rotating at low speed, operability of the electric work machine may be impaired due to the insufficient output torque.

An object of one aspect of the present disclosure is to provide a technology for controlling a brushless motor in an electric work machine so as to be capable of appropriately responding to each of a situation in which high-speed rotation is desired and a situation in which high output torque is desired.

In the present disclosure, ordinal numbers such as “first” and “second” are merely intended to distinguish the elements from each other, and are not intended to limit the order and/or number of the elements. Thus, the first element may be referred to as the second element, and similarly, the second element may be referred to as the first element. In addition, the first element may be provided without the second element, and similarly, the second element may be provided without the first element.

One aspect of the present disclosure provides an electric work machine including a brushless motor, a drive circuit, and a control circuit.

The brushless motor is configured to drive an end tool.

The drive circuit is configured to (i) receive a DC power from a DC power supply, (ii) generate three-phase power from the DC power received, and (iii) supply the three-phase power generated to the brushless motor to drive the brushless motor.

The control circuit is configured to selectively set an operation mode of the control circuit to one of a first mode and a second mode.

The control circuit is configured to control the brushless motor through the drive circuit according to a first control scheme, based on the operation mode being set to the first mode. The first control scheme (i) is a control scheme other than field-oriented control or (ii) includes a first field-oriented control.

The control circuit is configured to control the brushless motor through the drive circuit according to a second control scheme, based on the operation mode being set to the second mode. The second control scheme (i) is different from the first control scheme and (ii) includes a second field-oriented control. The first field-oriented control is different from the second field-oriented control.

The thus-configured electric work machine is capable of appropriately responding to each of a situation in which high-speed rotation is desired and a situation in which high output torque is desired.

Another aspect of the present disclosure provides a method for controlling a brushless motor in an electric work machine, the method including:
selectively setting an operation mode of the electric work machine equipped with the brushless motor to one of a first mode and a second mode;
controlling driving of the brushless motor according to a control scheme other than field-oriented control or by a first field-oriented control while the operation mode is set to the first mode; and
controlling the driving of the brushless motor by a second field-oriented control while the operation mode is set to the second mode. The first field-oriented control is different from the second field-oriented control.

Such a method makes it possible to control the brushless motor so as to be capable of appropriately responding to each of a situation in which high-speed rotation is desired and a situation in which high output torque is desired.

### BRIEF DESCRIPTION OF THE DRAWINGS

Example embodiments of the present disclosure will be described hereinafter with reference to the accompanying drawings, in which:

FIG. 1 is a perspective view of an electric work machine according to a first embodiment;

FIG. 2 is an explanatory diagram showing an electrical configuration of the electric work machine according to the first embodiment;

FIG. 3 is a block diagram showing functions of a control circuit in a second mode in the first embodiment;

FIG. 4 is a block diagram showing functions of the control circuit in a first mode in the first embodiment;

FIG. 5 is an explanatory diagram schematically illustrating differences between the first mode and the second mode;

FIG. 6 is an explanatory diagram showing an operation example in the second mode in the first embodiment;

FIG. 7 is an explanatory diagram showing a first operation example in the first mode in the first embodiment;

FIG. 8 is an explanatory diagram showing a second operation example in the first mode in the first embodiment;

FIG. 9 is a flowchart of a motor control process according to the first embodiment;

FIG. 10 is a flowchart of an operation information acquisition process according to the first embodiment;

FIG. 11 is a flowchart of an operation mode switching process according to the first embodiment;

FIG. 12 is an explanatory diagram showing a first operation example in the second mode in a second embodiment;

FIG. 13 is an explanatory diagram showing a second operation example in the second mode in the second embodiment;

FIG. 14 is an explanatory diagram explaining overmodulation control in a third embodiment;

FIG. 15 is a flowchart of a motor control process according to a fourth embodiment;

FIG. 16 is a flowchart of a motor control process according to a fifth embodiment;

FIG. 17 is a flowchart of a specific mode monitoring process according to the fifth embodiment;

FIG. 18 is a flowchart of a motor control process according to a sixth embodiment; and

FIG. 19 is a flowchart of a specific mode monitoring process according to the sixth embodiment.

### DETAILED DESCRIPTION OF EXEMPLARY EMBODIMENTS

### 1. Overview of Embodiments

One embodiment may provide an electric work machine including at least any one of:
Feature 1: a brushless motor (or brushless DC motor);
Feature 2: the brushless motor is configured to drive an end tool (or work tool, or driven implement, or tip accessory);
Feature 3: a drive circuit;
Feature 4: the drive circuit is configured to receive a DC power from a DC power supply;
Feature 5: the drive circuit is configured to generate three-phase power from the received DC power;
Feature 6: the drive circuit is configured to supply the generated three-phase power to the brushless motor to thereby drive the brushless motor;
Feature 7: a control circuit;
Feature 8: the control circuit is configured to selectively set an operation mode of the control circuit to one of a first mode and a second mode;
Feature 9: the control circuit is configured to control the brushless motor through the drive circuit according to a first control scheme, based on the operation mode being set to the first mode;
Feature 10: the first control scheme (i) is a control scheme other than field-oriented control (FOC) (or a control scheme different from FOC, or a control scheme not using FOC, or a non-FOC scheme) or (ii) includes first FOC;
Feature 11: the control circuit is configured to control the brushless motor through the drive circuit according to a second control scheme, based on the operation mode being set to the second mode; and
Feature 12: the second control scheme is different from the first control scheme.
Feature 13: the second control scheme includes second FOC different from the first FOC.

The electric work machine including at least Features 1 through 13 makes it possible to provide an electric work machine equipped with the brushless motor capable of appropriately responding to each of a high-speed priority situation and a high-torque priority situation. The high-speed priority situation corresponds to a situation in which high-speed rotation is desired. The high-torque priority situation corresponds to a situation in which high output torque is desired. For example, in the high-speed priority situation (or in a situation in which high output torque is not desired), the first control scheme may be employed. For example, in the high-torque priority situation (or in a situation in which high-speed rotation is not desired), the second control scheme may be employed.

The first mode may be understood as an operation mode in which the rotational speed takes priority over the output torque. Specifically, the first mode may be understood as an operation mode in which rotating the brushless motor at higher speed takes priority over rotating the brushless motor at higher output torque.

The second mode may be understood as an operation mode in which the output torque takes priority over the rotational speed. Specifically, the second mode may be understood as an operation mode in which rotating the brushless motor at higher output torque takes priority over rotating the brushless motor at higher speed.

The brushless motor may be classified as a permanent-magnet-type synchronous motor. The brushless motor may be referred to as a brushless DC motor. The brushless motor may include a stator and a rotor. The rotor may include a shaft that rotates together with the rotor.

The rotor and the shaft may pass through the stator. That is, the brushless motor may be of an inner-rotor type. Alternatively, the rotor may be rotatably disposed around an outer periphery of the stator, and the shaft may be disposed so as to pass through the stator. That is, the brushless motor may be of an outer-rotor type.

The rotor may include permanent magnets disposed along a circumferential direction of the rotor. The permanent magnets may be disposed such that magnetic poles are disposed along the circumferential direction on an outer peripheral surface of the rotor (e.g., such that N-poles and S-poles are alternately generated along the circumferential direction). The magnetic poles may have 2N (N is a natural number) magnetic poles.

The stator may include teeth and armature coils wound around the corresponding teeth. The armature coils may include one or more sets of three-phase coil groups. Each of the one or more sets of three-phase coil groups includes three coils coupled to each other. The three coils are disposed along the circumferential direction at intervals corresponding to 120 degrees in electrical angle. The three coils are wound around corresponding three of the teeth. The three coils may be star-connected or may be delta-connected. The one or more sets of three-phase coil groups may have M sets (M is a natural number) of three-phase coil groups. In other words, the one or more sets of three-phase coil groups may have 3M coils. In this case, the stator may include 3M teeth, and the 3M coils may be wound around the corresponding 3M teeth.

The brushless motor may include a first terminal, a second terminal, and a third terminal, which will be described below. The one or more sets of three-phase coil groups may be coupled to the first terminal, the second terminal, and/or the third terminal. The three-phase power (or three-phase AC power) may be input to the first terminal, the second terminal, and the third terminal. Supplying the three-phase power to the brushless motor includes applying three-phase voltages to the brushless motor and/or supplying three-phase currents to the brushless motor. The three-phase voltages include a first-phase voltage, a second-phase voltage, and a third-phase voltage, which are applied to the first through third terminals, respectively. The three-phase currents include a first-phase current, a second-phase current, and a third-phase current, which are supplied to the first through third terminals, respectively.

The brushless motor may be in the form of an interior permanent magnet synchronous motor (IPMSM). The brushless motor may be in the form of a surface permanent magnet synchronous motor (SPMSM).

The end tool may include any tool or implement capable of exerting an intended function directly or indirectly on the outside (or a work object) of the electric work machine. Examples of the end tool include various tool bits (e.g., drill bits and driver bits), various rotary blades (including saw chains), various blades other than rotary blades (including grinding wheels), and various fans (more specifically, blades). The various fans may be used in any electric work machines configured to suck or discharge air. Examples of this type of electric work machine include electric cleaners, electric dust collectors, and electric blowers. The end tool may be exposed to the outside of the electric work machine or may be housed inside the electric work machine.

The end tool may be (i) attached (or fixed) to the electric work machine or (ii) configured to be detachably attached to the electric work machine. The electric work machine may include a power transmission portion (or an output shaft) configured to transmit a rotational force of the brushless motor to the end tool. The end tool may be (i) attached (or fixed) to the power transmission portion or (ii) configured to be detachably attached to the power transmission portion.

The drive circuit may have any configuration capable of generating the three-phase power from the DC power. The drive circuit may include a three-phase bridge circuit described below. The three-phase bridge circuit may include three positive-side current paths, and/or three negative-side current paths, and/or three high-side switches (i.e., a first switch, a second switch, and a third switch), and/or three low-side switches (i.e., a fourth switch, a fifth switch, and a sixth switch).

The respective three positive-side current paths electrically couple the corresponding first through third terminals of the brushless motor to a positive electrode of the DC power supply. The respective three negative-side current paths electrically couple the corresponding first through third terminals to a negative electrode of the DC power supply. The respective three high-side switches are (i) located in the corresponding three positive-side current paths and (ii) configured to establish or interrupt the corresponding three positive-side current paths. The respective three low-side switches are (i) located in the corresponding three negative-side current paths and (ii) configured to establish or interrupt the corresponding three negative-side current paths.

Examples of the DC power supply include a battery described below and a DC power-supply circuit. The DC power-supply circuit may be configured to (i) receive AC power and (ii) convert the AC power into the DC power.

Each of the first through sixth switches may be in the form of a semiconductor switch or may be in the form different from the semiconductor switch.

Controlling the brushless motor by the control circuit through the drive circuit may be rephrased as controlling the drive circuit by the control circuit to thereby indirectly control the brushless motor. Controlling the brushless motor by the control circuit through the drive circuit may include (or mean) that the control circuit individually drives (i.e., turns on or off) the first through sixth switches.

FOC is also referred to as vector control. FOC is a control method that handles the three-phase currents supplied to the brushless motor in a d-q reference frame (also referred to as a d-q coordinate system). The d-q reference frame has a direct-axis (hereinafter abbreviated as “d-axis”) and a quadrature-axis (hereinafter abbreviated as “q-axis”), which are orthogonal to each other. FOC includes converting the three-phase currents into a d-axis current and a q-axis current. The d-axis current is a d-axis component of the three-phase currents, and the q-axis current is a q-axis component of the three-phase currents. FOC is a control method in which the d-axis current and the q-axis current are individually controlled. The d-axis is along a direction that is (i) perpendicular to a rotational axis of the rotor, (ii) directed radially outward from the rotational axis, and (iii) directed by the N-pole of the rotor. The q-axis is along a direction advanced by 90 degrees in electrical angle from the d-axis.

Supplemental description will be given of the d-axis current and the q-axis current. When the three-phase currents flow through the armature coils, magnetic flux is generated from the armature coils due to the three-phase currents (i.e., the armature coils generate a magnetic field). The magnetic flux (magnetic field) rotates. The magnetic flux can be vector-decomposed into d-axis flux and q-axis flux. The d-axis flux is a component in the d-axis direction in the magnetic flux, and the q-axis flux is a component in the q-axis direction in the magnetic flux. When the d-axis flux and the q-axis flux are defined in this manner, the d-axis current may be understood as a current component that generates the d-axis flux out of the total three-phase currents, and the q-axis current may be understood as a current component that generates the q-axis flux out of the total three-phase currents.

As is clear from such definitions of the d-axis current and the q-axis current, the d-axis current does not contribute to generation of torque of the rotor, and the q-axis current contributes to the generation of the torque of the rotor. A positive direction and a negative direction of the q-axis may be defined in any manner. For example, the positive direction of the q-axis may be a direction of torque applied to the rotor to accelerate the brushless motor, and the negative direction of the q-axis may be a direction opposite to the direction of the torque.

FOC may include converting a first-phase current value, a second-phase current value, and a third-phase current value into a d-axis actual current value and a q-axis actual current value. The first-phase current value, the second-phase current value, and the third-phase current value are values of the three-phase currents (i.e., the first-phase current, the second-phase current, and the third-phase current, respectively) actually flowing through the brushless motor. The d-axis actual current value is a d-axis component of the actual three-phase currents, and the q-axis actual current value is a q-axis component of the actual three-phase currents.

FOC may include generating or setting a d-axis current command value and/or a q-axis current command value. The d-axis current command value is a target value of the d-axis current, and the q-axis current command value is a target value of the q-axis current. The d-axis current command value and the q-axis current command value may be generated based on a difference between a target rotational speed and an actual rotational speed (e.g., such that the difference approaches zero).

FOC may include calculating a d-axis difference and/or a q-axis difference. The d-axis difference is a difference between the d-axis current command value and the d-axis actual current value, and the q-axis difference is a difference between the q-axis current command value and the q-axis actual current value.

FOC may include calculating a d-axis voltage command value based on the d-axis difference and/or calculating a q-axis voltage command value based on the q-axis difference. The d-axis voltage command value may be calculated such that the d-axis difference matches (or approaches) zero. The q-axis voltage command value may be calculated such that the q-axis difference matches (or approaches) zero. The d-axis voltage command value and the q-axis voltage command value may be calculated in any manners based on the d-axis difference and the q-axis difference, respectively. The d-axis voltage command value and the q-axis voltage command value may be calculated by, for example, proportional-integral (PI) control.

FOC may include converting the d-axis voltage command value and the q-axis voltage command value into three-phase voltage command values on a three-phase fixed coordinate system. The three-phase voltage command values include a first-phase voltage command value corresponding to a command value for the first-phase voltage, a second-phase voltage command value corresponding to a command value for the second-phase voltage, and a third-phase voltage command value corresponding to a command value for the third-phase voltage.

FOC may include controlling the drive circuit so as to apply the three-phase voltages corresponding to the first- through third-phase voltage command values to the brushless motor. Specifically, FOC may individually control the first through sixth switches such that the three-phase voltages corresponding to the first- through third-phase voltage command values are applied to the brushless motor. The control circuit may output first through sixth drive signals to the first through sixth switches, respectively, to thereby individually control (i.e., turn on or off) the first through sixth switches.

The second FOC may be different from the first FOC in any manner. The first field-oriented control and the second field-oriented control may differ from each other in (i) at least one control region in a d-q reference frame and/or (ii) at least one control condition related to controlling three-phase currents and/or three-phase voltages. A transition region of a current vector described below in the d-q reference frame may be partially or completely different between in the first FOC and in the second FOC.

In a case where the first control scheme is a control scheme other than FOC, the second FOC may be simply referred to as “FOC”. That is, in this case, the second FOC may include any types of FOC.

One embodiment may include, in addition to or in place of at least any one of Features 1 through 13, at least any one of:
Feature 14: the first control scheme is the control scheme other than FOC; and
Feature 15: the first control scheme includes square-wave control (also referred to as six-step control, trapezoidal control, or rectangular-wave control). The square-wave control may include applying square-wave voltages (also referred to as rectangular-wave voltages or block-shaped voltages or trapezoidal voltages) from the drive circuit to the brushless motor.

In the electric work machine including at least Features 1 through 15, driving of the brushless motor can be controlled simply and efficiently in the first mode.

The term "square-wave control" may refer to (i) a control scheme opposed to the sinusoidal, continuous modulation used in the FOC and/or (ii) a control scheme in which a motor is driven by the drive circuit in a non-sinusoidal manner. The square-wave control may encompass control schemes that may be referred to in the art as six-step control or trapezoidal control. The square-wave control may involve discrete switching of drive circuit states based on predetermined or dynamically adjusted electrical angles. Examples of such control include six-step commutation, conduction angle control, and lead angle control.

Each of the square-wave voltages has a square-wave or other non-sinusoidal waveform. Each of the square-wave voltages may be generated based on discrete switching states of the drive circuit. The respective square-wave voltages may be applied to the corresponding first through third terminals of the brushless motor.

Each of the square-wave voltages is not limited to a voltage that varies strictly in a square waveform. Even if the strict square waveform is distorted due to disturbances such as noise or other various factors (e.g., back-EMF), it may be regarded as the voltage that varies strictly in a square waveform and/or that has a square waveform. For example, a voltage that varies along a trapezoidal shape or a shape similar thereto may also be regarded as the square-wave voltage. Applying the square-wave voltages may include that each of the first-phase voltage, the second-phase voltage, and the third-phase voltage is in the form of the square-wave voltage (or has the square waveform).

The square-wave control may include generating three phase currents and/or three square-wave voltages having square or trapezoidal or rectangular waveform characteristics. The square-wave control is applicable to, but not limited to, motors having trapezoidal back-EMF characteristics.

The square-wave control may include outputting square-wave drive signals to the drive circuit to thereby operate the drive circuit. The square-wave drive signals may be signals defining a six-step commutation.

A magnitude of the three-phase power supplied to the brushless motor may be controlled by a conduction angle and/or a lead angle, which will be described below. The magnitude of the three-phase power may be controlled by (i) driving the drive circuit with pulse-width modulation signals and (ii) adjusting a duty ratio of the pulse-width modulation signals.

One embodiment may include, in addition to or in place of at least any one of Features 1 through 15, at least any one of:
Feature 16: the drive circuit includes a three-phase bridge circuit;
Feature 17: the three-phase bridge circuit has six switches;
Feature 18: the first control scheme includes turning on each of the six switches continuously or intermittently during a period from a corresponding on-timing until the brushless motor rotates by an angle corresponding to a conduction angle;
Feature 19: the first control scheme includes lead angle control (also referred to as phase-advance control) and/or conduction angle control (also referred to as energization angle control);
Feature 20: the lead angle control includes advancing the on-timing of each of the six switches by an angle (or a time) corresponding to a lead angle from a reference timing;
Feature 21: the lead angle control includes varying the lead angle according to an operating state of the brushless motor; and
Feature 22: the conduction angle control includes varying the conduction angle according to an operating state of the brushless motor.

In the electric work machine including at least Features 1 through 22, the brushless motor can be driven more efficiently in the first mode.

The “first control scheme” in Features 18 and 19 may be rephrased as the “square-wave control”.

The conduction angle and the lead angle may be expressed in electrical angle. The conduction angle may be set within a range of 120 to 180 degrees in electrical angle, for example. The reference timing may occur each time the brushless motor rotates by 60 degrees in electrical angle (or each time its rotation by 60 degrees in electrical angle is detected).

One embodiment may include, in addition to or in place of at least any one of Features 1 through 22, at least any one of:
Feature 23: the brushless motor includes a first terminal, a second terminal, and a third terminal;
Feature 24: the first terminal, the second terminal, and the third terminal are configured to receive, from the drive circuit, respective three-phase currents corresponding to the three-phase power;
Feature 25: the first control scheme includes the first FOC; and
Feature 26: the second FOC includes supplying the three-phase currents to the brushless motor such that a current vector (more specifically, the tip thereof) of the three-phase currents moves along a maximum torque per ampere (MTPA) curve of the brushless motor in a d-q reference frame. The d-q reference frame has a d-axis and a q-axis orthogonal to each other. The current vector is a vector sum of the d-axis current and the q-axis current. In other words, the current vector is a sum of a d-axis current vector and a q-axis current vector. The d-axis current corresponds to a d-axis component in the three-phase currents. The q-axis current corresponds to a q-axis component in the three-phase currents. The d-axis current vector is a vector that (i) originates from the origin in the d-q reference frame, (ii) is along the d-axis, and (iii) has a magnitude of the d-axis current. The q-axis current vector is a vector that (i) originates from the origin in the d-q reference frame, (ii) is along the q-axis, and (iii) has a magnitude of the q-axis current. In the second FOC, the current vector may constantly move along the MTPA curve, or the current vector may move off the MTPA curve depending on an operating state or the like.

In the electric work machine including at least Features 1 through 13 and 23 through 26, the brushless motor can be efficiently driven while causing the brushless motor to generate high torque in the second mode.

One embodiment may include, in addition to or in place of at least any one of Features 1 through 26, at least any one of:
Feature 27: the first FOC includes field-weakening control (also referred to as flux‑weakening control);
Feature 28: the field-weakening control includes supplying the three-phase currents to the brushless motor such that the current vector (more specifically, the tip thereof) moves within a first region in the d-q reference frame; Feature
29: the first region does not include the MTPA curve; and Feature
30: the first region corresponds to a region on a d-axis negative side relative to the MTPA curve.

In the electric work machine including at least Features 1 through 13 and 23 through 30, a decrease in the output torque of the brushless motor can be reduced while rotating the brushless motor at high speed in the first mode. That is, in the first mode as well, the brushless motor can be rotated at higher speed than in the second mode by weakening a field flux more than in FOC performed in the second mode (than in the second FOC) while basically using FOC.

The field-weakening control may include causing the current vector to move along a constant current circle from the MTPA curve toward a d-axis negative direction. The constant current circle is also referred to as a current limit circle.

The field-weakening control may include causing the current vector to move along a maximum torque per voltage (MTPV) curve (or a maximum torque per flux (MTPF) curve) of the brushless motor in the d-q reference frame.

The field-weakening control may include causing the current vector to move along a voltage limit ellipse of the brushless motor in the d-q reference frame. The voltage limit ellipse is also referred to as a constant flux linkage ellipse or a constant back-EMF ellipse. The field-weakening control may include causing the current vector to move along the voltage limit ellipse in a region thereof on a d-axis positive side relative to the MTPV curve (or MTPF curve).

One embodiment may include, in addition to or in place of at least any one of Features 1 through 30, at least any one of:
Feature 31: the first FOC includes applying an overmodulation voltage from the drive circuit to each of the first terminal, the second terminal, and the third terminal;
Feature 32: a magnitude of the overmodulation voltage varies along a reference sine wave. The reference sine wave has an amplitude greater than a magnitude of a DC voltage. The DC voltage may be applied from the DC power supply to the drive circuit. The reference sine wave may be a virtual sine wave.; and Feature
33: the magnitude of the overmodulation voltage is maintained at a magnitude of the DC voltage in a period in which a magnitude of the reference sine wave is greater than the magnitude of the DC voltage.

In the electric work machine including at least Features 1 through 13, 23 through 26, and 31 through 33, a voltage utilization factor of the DC voltage of the DC power supply can be improved in the first mode. This makes it possible, in the first mode as well, to rotate the brushless motor at higher speed than in the second mode while basically using FOC.

The control circuit may generate the overmodulation voltage in any manner. For example, the control circuit may generate a voltage command instructing generation of a sine wave voltage. The sine wave voltage has an amplitude greater than the magnitude of the DC voltage of the DC power supply. The control circuit basically causes the drive circuit to output a voltage indicated by the voltage command (i.e., a voltage along the reference sine wave); however, the control circuit may cause the drive circuit to output a voltage that is the same as or substantially the same as the DC voltage in a period in which the voltage indicated by the voltage command is higher than the DC voltage.

One embodiment may include, in addition to or in place of at least any one of Features 1 through 33, at least any one of:
Feature 34: a manual switch;
Feature 35: the manual switch is configured to allow a user of the electric work machine to perform a first manual operation and a second manual operation;
Feature 36: the control circuit is configured to set the operation mode to the first mode based on the first manual operation being performed on the manual switch; and
Feature 37: the control circuit is configured to set the operation mode to the second mode based on the second manual operation being performed on the manual switch.

In the electric work machine including at least Features 1 through 13 and 34 through 37, a user can switch the operation mode as desired at any timing.

One embodiment may include, in addition to or in place of at least any one of Features 1 through 37, at least any one of:
Feature 38: the control circuit is configured to set the operation mode to the first mode based on a first-mode switching requirement being met. The first-mode switching requirement may define a condition for setting or switching the operation mode to the first mode;
Feature 39: the control circuit is configured to switch the operation mode to the first mode based on (i) the operation mode being set to the second mode and (ii) the first-mode switching requirement being met;
Feature 40: the control circuit is configured to set the operation mode to the second mode based on a second-mode switching requirement being met. The second-mode switching requirement may define a condition for setting or switching the operation mode to the second mode; and
Feature 41: the control circuit is configured to switch the operation mode to the second mode based on (i) the operation mode being set to the first mode and (ii) the second-mode switching requirement being met.

In the electric work machine including at least Features 1 through 13 and 38 through 41, appropriately setting the first-mode switching requirement and the second-mode switching requirement makes it possible to appropriately set the operation mode to the first mode or the second mode while reducing the burden on the user.

One embodiment may include, in addition to or in place of at least any one of Features 1 through 41, at least any one of:
Feature 42: the second-mode switching requirement is met based on a load torque being equal to or higher than a first torque threshold. The load torque is applied to the brushless motor;
Feature 43: the load torque is applied to the brushless motor via the end tool;
Feature 44: the first-mode switching requirement is met based on the load torque being equal to or lower than a second torque threshold;
Feature 45: the second torque threshold is less than the first torque threshold; and
Feature 46: the second torque threshold is greater than zero.

In the electric work machine including at least Features 1 through 13 and 38 through 46, the operation mode can be appropriately set according to the load torque.

The first torque threshold may be a value at which the operation mode should be switched (or is preferably switched) to the second mode when the load torque increases to or exceeds the first torque threshold during the first mode. The second torque threshold may be a value at which the operation mode should be switched (or is preferably switched) to the first mode when the load torque decreases to or falls below the second torque threshold during the second mode.

The electric work machine may include a torque sensor configured to detect the load torque. The torque sensor may be configured to output a torque signal indicating the load torque. The control circuit may be configured to (i) receive the torque signal and (ii) acquire the load torque based on the torque signal. Alternatively, the control circuit may be configured to (i) acquire a physical quantity indicating the load torque directly or indirectly (i.e., reflecting the load torque) and (ii) calculate (or estimate) the load torque from the physical quantity. The control circuit may determine whether the first-mode switching requirement and the second-mode switching requirement are met based on the acquired or calculated load torque.

One embodiment may include, in addition to or in place of at least any one of Features 1 through 46, at least any one of:
Feature 47: the second-mode switching requirement is met based on a magnitude of a bus current being equal to or greater than a first current threshold. The bus current is a current supplied from the DC power supply to the brushless motor through the drive circuit. In other words, the bus current is a current supplied from the DC power supply to the drive circuit at the time when a current is supplied from the DC power supply to the brushless motor through the drive circuit;
Feature 48: the first-mode switching requirement is met based on the magnitude of the bus current being equal to or less than a second current threshold;
Feature 49: the second current threshold is less than the first current threshold; and
Feature 50: the second current threshold is greater than zero.

In the electric work machine including at least Features 1 through 13, 38 through 41, and 47 through 50, the operation mode can be appropriately set according to the magnitude of the bus current.

The first current threshold may be a value at which the operation mode should be switched (or is preferably switched) to the second mode when the magnitude of the bus current increases to or exceeds the first current threshold during the first mode. The second current threshold may be a value at which the operation mode should be switched (or is preferably switched) to the first mode when the magnitude of the bus current decreases to or falls below the second current threshold during the second mode.

The electric work machine may include a bus current detection circuit configured to detect the magnitude of the bus current. The bus current detection circuit may be configured to output a bus current detection signal indicating the magnitude of the bus current. The control circuit may be configured to (i) receive the bus current detection signal and (ii) acquire the magnitude of the bus current based on the bus current detection signal. The control circuit may determine whether the first-mode switching requirement and the second-mode switching requirement are met based on the acquired magnitude of the bus current.

One embodiment may include, in addition to or in place of at least any one of Features 1 through 50, at least any one of:
Feature 51: the second-mode switching requirement is met based on a current level being equal to or higher than a third current threshold. The current level indicates an amplitude of the three-phase currents directly or indirectly;
Feature 52: the first-mode switching requirement is met based on the current level being equal to or lower than a fourth current threshold;
Feature 53: the fourth current threshold is less than the third current threshold; and Feature
54: the fourth current threshold is greater than zero.

In the electric work machine including at least Features 1 through 13, 23, 24, 38 through 41, and 51 through 54, the operation mode can be appropriately set according to the above-described current level.

The third current threshold may be a value at which the operation mode should be switched (or is preferably switched) to the second mode when the current level increases to or exceeds the third current threshold during the first mode. The fourth current threshold may be a value at which the operation mode should be switched (or is preferably switched) to the first mode when the current level decreases to or falls below the fourth current threshold during the second mode.

The current level may correspond to the amplitude of any one of the above-described first- through third-phase currents. Alternatively, the current level may correspond to a representative value (e.g., an average value, a median value, or an RMS value) of the amplitudes of the first- through third-phase currents. Alternatively, the current level may correspond to a magnitude of a current vector of the three-phase currents in the d-q reference frame.

The electric work machine may include at least one phase current detection circuit (or a phase current detection sensor). The at least one phase current detection circuit is configured to detect a magnitude of at least one of the three-phase currents (i.e., the above-described first- through third-phase currents). Each of the at least one phase current detection circuit may be configured to output a phase current detection signal indicating the magnitude of the corresponding phase current. The control circuit may be configured to (i) receive the phase current detection signal from the at least one phase current detection sensor and (ii) acquire the current level based on the phase current detection signal. Alternatively, the control circuit may calculate the magnitude of the current vector based on the received phase current detection signal to acquire the calculated magnitude of the current vector as the current level. The control circuit may determine whether the first-mode switching requirement and the second-mode switching requirement are met based on the acquired current level.

One embodiment may include, in addition to or in place of at least any one of Features 1 through 54, at least any one of:
Feature 55: the drive circuit is configured to receive a DC voltage corresponding to the DC power from the DC power supply;
Feature 56: the second-mode switching requirement is met based on a magnitude of the DC voltage being equal to or greater than a first voltage threshold;
Feature 57: the first-mode switching requirement is met based on the magnitude of the DC voltage being equal to or less than a second voltage threshold;
Feature 58: the second voltage threshold is less than the first voltage threshold; and Feature 59: the second voltage threshold is greater than zero.

In the electric work machine including at least Features 1 through 13, 38 through 41, and 55 through 59, the operation mode can be appropriately set according to the magnitude of the DC voltage.

The first voltage threshold may be a value at which the operation mode should be switched (or is preferably switched) to the second mode when the magnitude of the DC voltage increases to or exceeds the first voltage threshold during the first mode. The second voltage threshold may be a value at which the operation mode should be switched (or is preferably switched) to the first mode when the magnitude of the DC voltage decreases to or falls below the second voltage threshold during the second mode.

The electric work machine may include a power-supply voltage detection sensor configured to detect the magnitude of the DC voltage. The power-supply voltage detection sensor may be configured to output a voltage detection signal indicating the magnitude of the DC voltage. The control circuit may be configured to (i) receive the voltage detection signal and (ii) acquire the magnitude of the DC voltage based on the voltage detection signal. The control circuit may determine whether the first-mode switching requirement and the second-mode switching requirement are met based on the acquired magnitude of the DC voltage.

One embodiment may include, in addition to or in place of at least any one of Features 1 through 59, at least any one of:
Feature 60: the second-mode switching requirement is met based on a temperature of the drive circuit being equal to or lower than a first temperature threshold;
Feature 61: the first-mode switching requirement is met based on the temperature of the drive circuit being equal to or higher than a second temperature threshold;
Feature 62: the first temperature threshold is less than the second temperature threshold; and
Feature 63: the first temperature threshold is greater than zero.

In the electric work machine including at least Features 1 through 13, 38 through 41, and 60 through 63, the operation mode can be appropriately set according to the temperature of the drive circuit (hereinafter referred to as “drive circuit temperature”).

The first temperature threshold may be a value at which the operation mode should be switched (or is preferably switched) to the second mode when the drive circuit temperature decreases to or falls below the first temperature threshold during the first mode. The second temperature threshold may be a value at which the operation mode should be switched (or is preferably switched) to the first mode when the drive circuit temperature increases to or exceeds the second temperature threshold during the second mode.

The electric work machine may include a first temperature detection circuit configured to detect the drive circuit temperature. The first temperature detection circuit may be configured to output a first temperature detection signal indicating the drive circuit temperature. The control circuit may be configured to (i) receive the first temperature detection signal and (ii) acquire the drive circuit temperature based on the first temperature detection signal. The control circuit may determine whether the first-mode switching requirement and the second-mode switching requirement are met based on the acquired drive circuit temperature.

One embodiment may include, in addition to or in place of at least any one of Features 1 through 63, at least any one of:
Feature 64: the second-mode switching requirement is met based on a temperature of the brushless motor being equal to or lower than a third temperature threshold;
Feature 65: the first-mode switching requirement is met based on the temperature of the brushless motor being equal to or higher than a fourth temperature threshold;
Feature 66: the third temperature threshold is less than the fourth temperature threshold; and
Feature 67: the third temperature threshold is greater than zero.

In the electric work machine including at least Features 1 through 13, 38 through 41, and 64 through 67, the operation mode can be appropriately set according to the temperature of the brushless motor (hereinafter referred to as “motor temperature”).

The third temperature threshold may be a value at which the operation mode should be switched (or is preferably switched) to the second mode when the motor temperature decreases to or falls below the third temperature threshold during the first mode. The fourth temperature threshold may be a value at which the operation mode should be switched (or is preferably switched) to the first mode when the motor temperature increases to or exceeds the fourth temperature threshold during the second mode.

The electric work machine may include a second temperature detection circuit configured to detect the motor temperature. The second temperature detection circuit may be configured to output a second temperature detection signal indicating the motor temperature. The control circuit may be configured to (i) receive the second temperature detection signal and (ii) acquire the motor temperature based on the second temperature detection signal. The control circuit may determine whether the first-mode switching requirement and the second-mode switching requirement are met based on the acquired motor temperature.

One embodiment may include, in addition to or in place of at least any one of Features 1 through 67, at least any one of:
Feature 68: the DC power supply includes a battery;
Feature 69: the second-mode switching requirement is met based on a temperature of the battery being equal to or lower than a fifth temperature threshold;
Feature 70: the first-mode switching requirement is met based on the temperature of the battery being equal to or higher than a sixth temperature threshold;
Feature 71: the fifth temperature threshold is less than the sixth temperature threshold; and
Feature 72: the fifth temperature threshold is greater than zero.

In the electric work machine including at least Features 1 through 13, 38 through 41, and 68 through 72, the operation mode can be appropriately set according to the temperature of the battery (hereinafter referred to as “battery temperature”).

The fifth temperature threshold may be a value at which the operation mode should be switched (or is preferably switched) to the second mode when the battery temperature decreases to or falls below the fifth temperature threshold during the first mode. The sixth temperature threshold may be a value at which the operation mode should be switched (or is preferably switched) to the first mode when the battery temperature increases to or exceeds the sixth temperature threshold during the second mode.

The electric work machine may include a third temperature detection circuit configured to detect the battery temperature. The third temperature detection circuit may be configured to output a third temperature detection signal indicating the battery temperature. The control circuit may be configured to (i) receive the third temperature detection signal and (ii) acquire the battery temperature based on the third temperature detection signal. The control circuit may determine whether the first-mode switching requirement and the second-mode switching requirement are met based on the acquired battery temperature.

In a case where the electric work machine includes a battery port described below, the battery pack may be configured to transmit the third temperature detection signal to the control circuit through communication therewith. In this case, the control circuit may be configured to (i) receive the third temperature detection signal from the battery pack through the communication therewith and (ii) acquire the battery temperature based on the received third temperature detection signal. Such communication includes wired communication and wireless communication.

In addition to or in place of at least any one of Features 1 through 72, one embodiment may include:
Feature 73: the control circuit is configured to switch the operation mode to the first mode in response to (i) the operation mode being set to the second mode and (ii) the brushless motor having been continuously controlled according to the second control scheme for a first threshold time or longer.

In the electric work machine including at least Features 1 through 13, 34 through 37, and 73, heat generation of the electric work machine can be reduced. The “heat generation of the electric work machine” as used herein may include heat generation of the drive circuit, heat generation of the brushless motor, and/or heat generation of the DC power supply.

Specifically, generation of the heat by the electric work machine in the second mode may be greater than that in the first mode. Therefore, in a case where the brushless motor has been continuously driven in the second mode for the first threshold time or longer, the operation mode is automatically switched to the first mode, thereby enabling reduction or prevention of the heat generation (or overheating) of the electric work machine.

In addition to or in place of at least any one of Features 1 through 73, one embodiment may include:
Feature 74: the control circuit is configured to stop the supply of the three-phase power from the drive circuit to the brushless motor in response to (i) the operation mode being set to the second mode and (ii) the brushless motor having been continuously controlled according to the second control scheme for a second threshold time or longer. The second threshold time may be longer than, equal to, or shorter than the first threshold time.

In the electric work machine including at least Features 1 through 13, 34 through 37, and 74, the heat generation of the electric work machine can be further reduced or prevented.

In the electric work machine including at least Features 1 through 13 and 75 through 77, the operation mode can be appropriately set according to the attached device.

One embodiment may include, in addition to or in place of at least any one of Features 1 through 74, at least any one of:
Feature 75: the control circuit is configured to acquire attached device information. The attached device information is information regarding an attached device attached to the electric work machine;
Feature 76: the control circuit is configured to set the operation mode to the first mode based on the attached device information meeting a first setting requirement; and
Feature 77: the control circuit is configured to set the operation mode to the second mode based on the attached device information meeting a second setting requirement.

The first setting requirement may define a condition for setting or switching the operation mode to the first mode. The second setting requirement may define a condition for setting or switching the operation mode to the second mode.

The attached device may be detachably attached to the electric work machine, or may be non-detachably attached (i.e., may be fixed) to the electric work machine.

One embodiment may include, in addition to or in place of at least any one of Features 1 through 77, at least any one of:
Feature 78: a battery port configured to allow a battery pack housing the battery to be detachably attached thereto. The battery pack may correspond to the attached device;
Feature 79: the control circuit is configured to acquire battery information from the battery pack attached to the battery port;
Feature 80: the battery information indicates performance of the battery directly or indirectly; and
Feature 81: the attached device information includes the battery information.

In the electric work machine including at least Features 1 through 13, 68, and 75 through 81, the operation mode can be appropriately set according to the performance of the battery.

One embodiment may include, in addition to or in place of at least any one of Features 1 through 81, at least any one of:
Feature 82: the battery has internal resistance. The internal resistance may correspond to the performance of the battery;
Feature 83: the battery information includes a magnitude of the internal resistance;
Feature 84: the first setting requirement is met based on the magnitude of the internal resistance being equal to or greater than a first threshold;
Feature 85: the second setting requirement is met based on the magnitude of the internal resistance being equal to or less than a second threshold;
Feature 86: the second threshold is less than the first threshold; and
Feature 87: the second threshold is greater than zero.

In the electric work machine including at least Features 1 through 13, 68, and 75 through 87, the operation mode can be appropriately set according to the internal resistance of the battery.

The first threshold may be a value at which the operation mode should be switched (or is preferably switched) to the first mode when the magnitude of the internal resistance increases to or exceeds the first threshold during the second mode. The second threshold may be a value at which the operation mode should be switched (or is preferably switched) to the second mode when the magnitude of the internal resistance decreases to or falls below the second threshold during the first mode.

Specifically, the higher the internal resistance of the battery is, the higher the possibility that the battery has deteriorated is. That is, the internal resistance of the battery indirectly indicates a degree of deterioration of the battery. If the operation mode is set to the second mode in a state where the battery is deteriorated, sufficient output torque is not obtained, or a burden may be placed on the battery to thereby accelerate the deterioration of the battery. Therefore, the battery is driven in the second mode when the internal resistance of the battery is low, and the battery is driven in the first mode when the internal resistance of the battery is high, thereby enabling reduction of the burden on the battery.

One embodiment may include, in addition to or in place of at least any one of Features 1 through 87, at least any one of:
Feature 88: the control circuit is configured to acquire model information from the battery pack attached to the battery port. The model information indicates a model of the battery pack; and
Feature 89: the attached device information includes the model information.

In the electric work machine including at least Features 1 through 13, 68, 75 through 78, 88, and 89, the operation mode can be appropriately set according to the model of the battery pack.

The model of the battery pack may be information by which specifications, performance, and/or a physical configuration of the battery pack can be identified. Examples of such information include a rated voltage value of the battery pack, a rated capacity of the battery pack, types of battery cells constituting the battery, a maximum output current value, which is a maximum value of a current that can be output from the battery pack, and/or a communication protocol.

The rated value of the DC voltage may differ depending on the model. Alternatively, the maximum output current value may differ depending on the model.

Therefore, for example, in a case where the model information indicates that the rated value of the DC voltage is low (e.g., equal to or less than a specified voltage value), the operation mode may be set to the first mode. In contrast, for example, in a case where the model information indicates that the rated value of the DC voltage is high (e.g., higher than the specified voltage value), the operation mode may be set to the second mode.

On the other hand, for example, in a case where the model information indicates that the maximum output current value is low (e.g., equal to or less than a specified current value), the operation mode may be set to the first mode. In contrast, for example, in a case where the model information indicates that the maximum output current value is high (e.g., higher than the specified current value), the operation mode may be set to the second mode.

One embodiment may include, in addition to or in place of at least any one of Features 1 through 89, at least any one of:
Feature 90: the control circuit is configured to acquire tool information. The tool information indicates a type of the end tool attached to the electric work machine; and
Feature 91: the attached device information includes the tool information.

In the electric work machine including at least Features 1 through 13, 75 through 77, 90, and 91, the operation mode can be appropriately set according to the type of the end tool.

Specifically, for example, a required (or desirable) output torque may differ depending on the type of the end tool. Also, for example, a required (or desirable) rotational speed may differ depending on the type of the end tool.

Therefore, for example, in a case where the tool information indicates that an end tool assumed (or desired) to be driven with high torque (e.g., equal to or higher than a specified torque) is attached, the operation mode may be set to the second mode. In contrast, for example, in a case where the tool information indicates that an end tool not assumed to be driven with high torque (or having a low necessity thereof) is attached, the operation mode may be set to the first mode.

On the other hand, for example, in a case where the tool information indicates that an end tool assumed (or desired) to be driven at high speed (e.g., equal to or higher than a specified speed) is attached, the operation mode may be set to the first mode. In contrast, for example, in a case where the tool information indicates that an end tool not assumed to be driven at high speed (or having a low necessity thereof) is attached, the operation mode may be set to the second mode.

One embodiment may include, in addition to or in place of at least any one of Features 1 through 91, at least any one of:
Feature 92: a maximum value of a rotational speed of the brushless motor in the first mode is greater than a maximum value of the rotational speed in the second mode; and
Feature 93: a maximum value of an output torque of the brushless motor in the second mode is greater than a maximum value of the output torque in the first mode.

In the electric work machine including at least Features 1 through 13, 92, and 93, the brushless motor can be rotated at higher speed in the first mode, while the brushless motor can be rotated at higher output torque in the second mode.

The maximum value of the rotational speed may be, for example, a no-load rotational speed. The maximum value of the output torque may be, for example, a maximum value of torque that can be output by electric power from the battery pack.

One embodiment may provide a method for controlling a brushless motor in an electric work machine, the method including at least any one of:
Feature 94: selectively setting an operation mode of the electric work machine equipped with the brushless motor to one of a first mode and a second mode;
Feature 95: controlling driving of the brushless motor according to a control scheme other than FOC (or without using FOC, or according to non-FOC scheme) or by first FOC (or by using the first FOC) while the operation mode is set to the first mode; and
Feature 96: controlling the driving of the brushless motor by second FOC (or by using the second FOC) while the operation mode is set to the second mode. The first FOC is different from the second FOC.

According to the method including at least Features 94 through 96, it is possible to provide an electric work machine equipped with a brushless motor capable of appropriately responding to each of a situation in which high-speed rotation is desired and a situation in which high output torque is desired.

In one embodiment, the control circuit may be integrated into a single electronic unit, or a single electronic device, or a single circuit board.

In one embodiment, the control circuit may be a combination of two or more electronic circuits, or two or more electronic units, or two or more electronic devices individually provided in the electric work machine.

In one embodiment, the control circuit may include a microcomputer (or microcontroller, or microprocessor), hardwired logic, a graphics processing unit (GPU), a neural processing unit (NPU), an artificial intelligence (AI) processor, an AI chip, an application-specific integrated circuit (ASIC), an application-specific standard product (ASSP), a programmable logic device (PLD), discrete electronic components, and/or combinations thereof. Examples of the PLD include a field-programmable gate array (FPGA), but are not limited thereto.

Examples of the electric work machine include various electric apparatuses (or electric apparatuses for work sites) (i) used (or capable of being used) at work sites of construction, manufacturing, agriculture, horticulture, civil engineering, construction, cleaning, do-it-yourself carpentry, and so on and (ii) configured to be driven by a DC power supply (e.g., a battery). The work sites are not limited to professional-use sites, but include household or personal work sites.

Specifically, examples of the electric work machine include electric tools for masonry work, metalworking, and woodworking; work machines for gardening; and devices for creating an environment of jobsites. More specifically, examples of the electric work machine include electric blowers, electric hammers, electric hammer drills, electric drills, electric vibrating drills, electric drivers, electric wrenches, electric grinders, electric circular saws, electric reciprocating saws, electric jig saws, electric cutters, electric chain saws, electric planes, electric nailing machines (including electric tackers), electric hedge trimmers, electric lawn mowers, electric lawn trimmers, electric hedge clippers, electric bush/grass cutters, electric cleaners, electric trowels, electric vibrators, electric rammers, electric compactors, electric pumps, electric pile drivers, electric concrete saws, electric screeds, electric cut-off saws, electric sprayers, electric spreaders, electric dust collectors, robot vacuum cleaners, robot lawn mowers, electric earth augers, electric scarifiers, battery-powered wheel-barrows, battery-powered bicycles, electric air inflators, coffee machines (or coffee makers), fan vests, and heating jackets.

In one embodiment, Features 1 through 96 may be combined in any combination. In one embodiment, any of Features 1 through 96 may be excluded.

### 2. Specific Example Embodiments

Some specific example embodiments will be provided hereinafter.

### 2-1. First Embodiment

The present first embodiment illustrates an electric work machine 1 described hereinafter. The electric work machine 1 of the first embodiment is in the form of an electric chain saw. However, the electric work machine 1 of this type is merely an example, and the present disclosure is applicable to electric work machines in any forms.

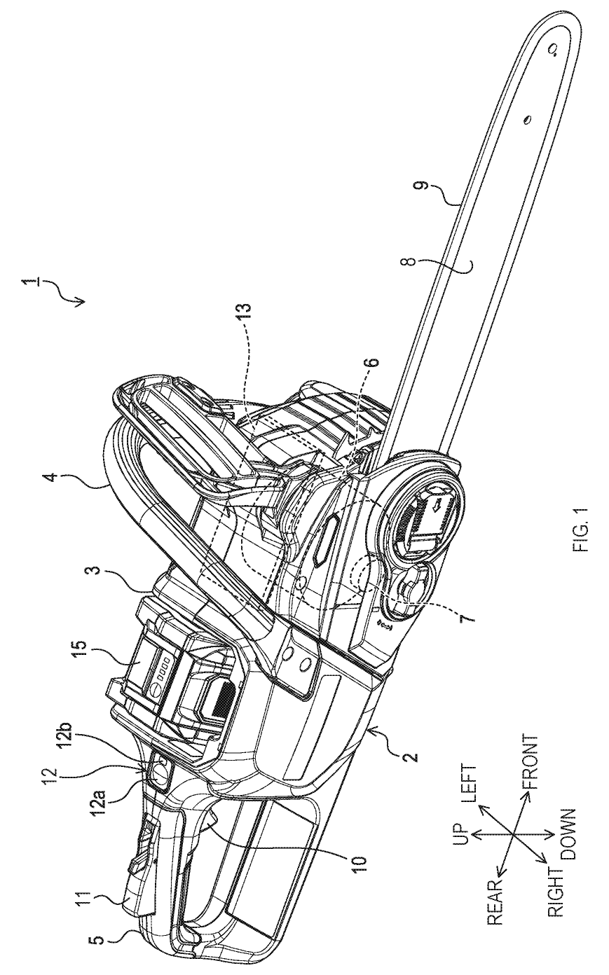

FIG. 1 includes an indication of the directions, namely, “up”, “down”, “front”, “rear”, “left”, and “right”. These directions are provided merely to facilitate a better understanding of the structure of the electric work machine 1, and not intended to limit the orientations of the electric work machine 1. The electric work machine 1 may be disposed in any orientations.

### 2-1-1. Mechanical Structure of Electric Work Machine

As shown in FIG. 1, the electric work machine 1 includes a housing 2. The housing 2 houses therein a motor 6, a power transmission portion (or an output shaft) 7, and a controller 13.

The electric work machine 1 includes a guide bar 8. The guide bar 8 is a plate-shaped member. The guide bar 8 protrudes from the housing 2 toward the front of the electric work machine 1.

The electric work machine 1 includes an end tool 9. The end tool 9 is an example of the “attached device” referred to in the Overview of Embodiments. The end tool 9 of this first embodiment is in the form of a saw chain. Specifically, the end tool 9 includes a plurality of cutters linked together. The end tool 9 is detachably attached to a peripheral edge of the guide bar 8.

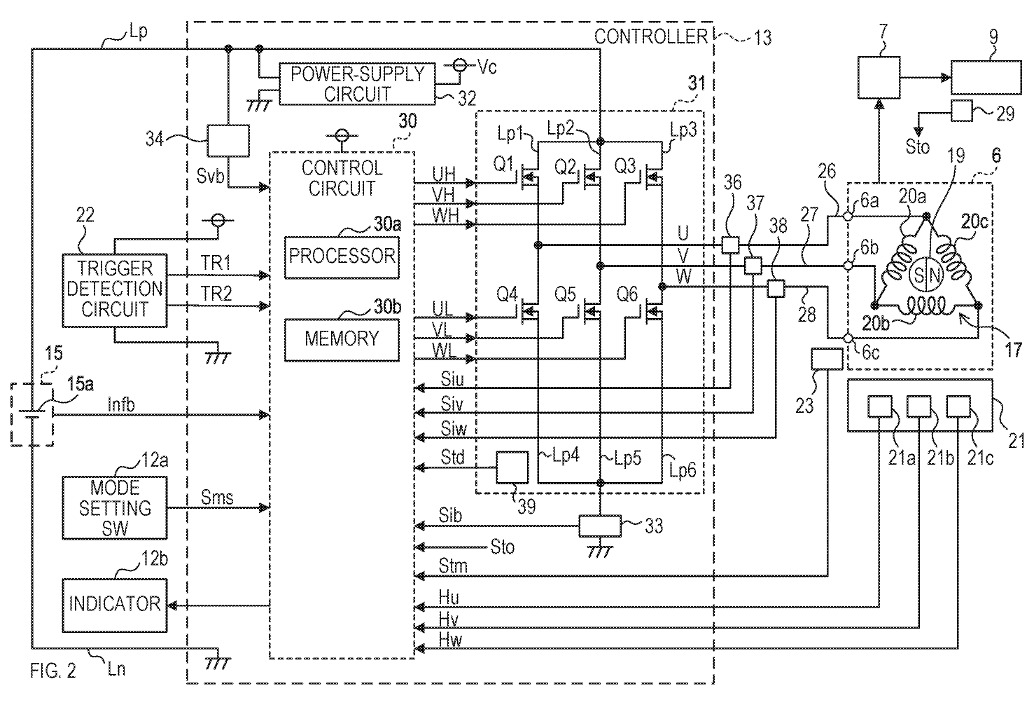

The power transmission portion 7 is directly or indirectly coupled to the motor 6 (more specifically, to a rotor 19; see FIG. 2). The power transmission portion 7 includes a sprocket (not shown) configured to allow the end tool 9 to be attached thereon. The power transmission portion 7 transmits a rotational force (or torque) of the motor 6 (more specifically, a rotational force (or torque) of the rotor 19) to the end tool 9 to thereby drive the end tool 9. Upon driving of the motor 6, the end tool 9 moves along the peripheral edge of the guide bar 8. This enables the end tool 9 to work on an object to be worked. Specifically, the end tool 9 is capable of cutting a workpiece of wood, metal, resin, or the like. The power transmission portion 7 (specifically, the sprocket) is an example of the “output shaft” referred to in the Overview of Embodiments.

The housing 2 includes a battery port 3 provided at a rear part thereof. The battery port 3 is where a battery pack 15 is detachably attached. The battery pack 15 is an example of the “attached device” referred to in the Overview of Embodiments.

FIG. 1 shows a state in which the battery pack 15 is attached to the battery port 3. The battery pack 15 houses a battery 15a (see FIG. 2) that is repeatedly rechargeable. The battery 15a is an example of the “DC power supply” referred to in the Overview of Embodiments.

Examples of the battery 15a include a lithium-ion battery. While the battery pack 15 is attached to the battery port 3, power of the battery 15a can be supplied to each part of the electric work machine 1. The battery 15a has an internal resistance. That is, the battery 15a can be equivalently regarded as a combination of a voltage source and an internal resistance coupled in series with each other. The magnitude of the internal resistance can vary depending on various factors, such as a degree of deterioration of the battery 15a. For example, the magnitude of the internal resistance can increase as the deterioration of the battery 15a progresses.

The electric work machine 1 includes a front handle 4 provided at an upper part of the housing 2. The front handle 4 is gripped by a user of the electric work machine 1. The electric work machine 1 includes a rear handle 5 provided rearward of the housing 2. The rear handle 5 is gripped by the user. The user can use the electric work machine 1 while, for example, gripping the front handle 4 with one hand (e.g., the left hand) and gripping the rear handle 5 with the other hand (e.g., the right hand).

The electric work machine 1 includes a trigger 10. The trigger 10 is manually operated by the user. Specifically, the trigger 10 is manually pulled upward. When the trigger 10 is manually operated (i.e., pulled), the motor 6 is driven. In this first embodiment, the trigger 10 is provided at the rear handle 5. Thus, the user can manually operate the trigger 10 while gripping the rear handle 5.

The electric work machine 1 includes a lock-off lever 11 in the vicinity of the trigger 10. The lock-off lever 11 is manually operated (e.g., pressed downward) by the user. When the lock-off lever 11 is not manually operated by the user, the lock-off lever 11 restricts movement of the trigger 10. While the lock-off lever 11 is manually operated by the user, the restriction on the trigger 10 is removed, thus allowing the user to manually operate the trigger 10. In this first embodiment, the lock-off lever 11 is provided at the rear handle 5. Thus, the user can manually operate the trigger 10 while gripping the rear handle 5 and manually operating the lock-off lever 11.

The electric work machine 1 includes an operation panel 12. In this first embodiment, the operation panel 12 is disposed on an upper surface of the housing 2 at a rear-end side thereof. The operation panel 12 includes a mode setting switch 12a and an indicator 12b.

The mode setting switch 12a receives various manual operations from the user. The mode setting switch 12a of this first embodiment is in the form of a momentary switch. While the mode setting switch 12ais pressed, the mode setting switch 12a outputs an operation signal Sms. While the mode setting switch 12a is not pressed, the mode setting switch 12a does not output the operation signal Sms.

The indicator 12b visually notifies the user of a state of the electric work machine 1. The indicator 12b of this first embodiment includes an LED (not shown). In the description below, “light up”, “blink”, and “turn off” for the indicator 12b respectively refer to “light up”, “blink”, and “turn off” for the LED.

### 2-1-2. Electrical Configuration of Electric Work Machine

An electrical configuration of the electric work machine 1 will be described with reference to FIG. 2. The electric work machine 1 includes the motor 6 and the controller 13 mentioned above.

In this first embodiment, the motor 6 is an inner-rotor-type brushless motor (more specifically, a three-phase brushless DC motor). In another embodiment, the motor 6 may be any other type of brushless motor (e.g., an outer-rotor-type brushless motor).

The motor 6 includes a stator 17. The stator 17 includes a first coil 20a, a second coil 20b, and a third coil 20c. The stator 17 includes a stator core (not shown) having teeth (not shown). The teeth are disposed at equal intervals along a rotational direction of the rotor 19. The first through third coils 20a, 20b, and 20c are each wound around a corresponding one of the teeth.

The first through third coils 20a, 20b, and 20c are delta-connected. However, the first through third coils 20a, 20b, and 20c may be connected in a manner other than the delta connection. For example, the first through third coils 20a, 20b, and 20c may be star-connected (or wye-connected).

The motor 6 includes the above-mentioned rotor 19 . The rotor 19 is disposed so as to pass through the stator 17 and is rotatably supported by a bearing (not shown). An outer peripheral surface of the rotor 19 has magnetic poles along the rotational direction. Specifically, N-poles and S-poles are disposed alternately on the outer peripheral surface of the rotor 19 along the rotational direction. As for the rotor 19 in FIG. 2, the N-poles are schematically indicated as “N”, and the S-poles are schematically indicated as “S”.

More specifically, the rotor 19 includes a rotor core (not shown) and permanent magnets (not shown) disposed in the rotor core along the rotational direction. The above-described magnetic poles are generated by these permanent magnets. In this first embodiment, the permanent magnets are embedded in the rotor core. That is, the motor 6 of this first embodiment is in the form of the above-mentioned IPMSM. However, the motor 6 may be in the form of a permanent-magnet-type synchronous motor (e.g., the above-mentioned SPMSM) other than the IPMSM.

For simplification of description, FIG. 2 schematically shows the motor 6 as if it were a brushless motor having a two-pole, three-slot (i.e., three-tooth) configuration. However, the brushless motor according to the present disclosure actually has four or more magnetic poles and six or more slots (i.e., six or more teeth). Nonetheless, the motor 6 may actually have a two-pole, three-slot configuration as shown.

The motor 6 includes a first terminal 6a, a second terminal 6b, and a third terminal 6c. The first terminal 6a is coupled to a first end of the first coil 20a and a first end of the third coil 20c. The second terminal 6b is coupled to a second end of the first coil 20a and a first end of the second coil 20b. The third terminal 6c is coupled to a second end of the second coil 20b and a second end of the third coil 20c.

The electric work machine 1 includes a position signal output circuit 21. The position signal output circuit 21 is disposed in the vicinity of the motor 6 (more specifically, in the vicinity of the rotor 19).

The position signal output circuit 21 includes a first rotation sensor 21a, a second rotation sensor 21b, and a third rotation sensor 21c. In this first embodiment, the first through third rotation sensors 21a through 21c are each a Hall sensor but not limited thereto.

The first through third rotation sensors 21a through 21c are disposed at a specified distance from the rotor 19 in a direction along the rotational axis thereof. The first through third rotation sensors 21a through 21c are spaced apart from each other by 120 degrees in electrical angle along the rotational direction of the rotor 19.

The first rotation sensor 21a outputs a first Hall signal Hu, the second rotation sensor 21b outputs a second Hall signal Hv, and the third rotation sensor 21c outputs a third Hall signal Hw. The first through third Hall signals Hu, Hv, and Hw are each in the form of a digital signal (i.e., a binary signal). A logical value of each of the first through third Hall signals Hu, Hv, and Hw is inverted every time the rotor 19 rotates by 180 degrees in electrical angle. The phases of the first through third Hall signals Hu, Hv, and Hw are offset from each other by 120 degrees in electrical angle.

The electric work machine 1 includes a power line Lp. The electric work machine 1 includes a positive terminal (not shown) and a negative terminal (not shown). When the battery pack 15 is attached to the battery port 3, the positive terminal is electrically coupled to a positive electrode of the battery 15a, and the negative terminal is electrically coupled to a negative electrode of the battery 15a. The power line Lp extends from the positive terminal to the controller 13. The electric work machine 1 includes a ground line Ln. The ground line Ln extends from the negative terminal to the controller 13. The battery pack 15 applies a voltage of the battery 15a (hereinafter referred to as “battery voltage”) across the power line Lp and the ground line Ln.

The controller 13 includes a power-supply circuit 32. The power-supply circuit 32 is coupled to the power line Lp to receive the battery voltage via the power line Lp. The power-supply circuit 32 generates a DC voltage (hereinafter referred to as “power-supply voltage”) Vc from the battery voltage.

The controller 13 includes a control circuit 30. The control circuit 30 is activated upon receiving a power-supply voltage Vc. The control circuit 30 is a microcomputer including a processor 30a and a memory 30b. The memory 30b is in the form of a semiconductor memory. The memory 30b includes a ROM, a RAM, and a rewritable non-volatile memory. The non-volatile memory is, for example, an EEPROM, a flash memory, an ReRAM, an FeRAM, or the like. Various functions of the control circuit 30 are implemented by execution, by the processor 30a, of a program stored in the memory 30b. Such execution of the program by the processor 30a results in performing a method corresponding to the program.

In another embodiment, the control circuit 30 may include an additional microcomputer. In still another embodiment, some or all of the functions implemented by the processor 30a may be implemented by one or more electronic components (e.g., an integrated circuit). In yet another embodiment, the control circuit 30 may be a logic circuit (or a hardwired logic connection) including two or more electronic components. In a still further embodiment, the control circuit 30 may include the above-mentioned GPU, NPU, AI processor, AI chip, ASIC, ASSP, and/or PLD.

The controller 13 includes a drive circuit 31. The drive circuit 31 is electrically coupled to the power line Lp and to the ground line Ln. The drive circuit 31 receives the battery voltage via the power line Lp and the ground line Ln. The drive circuit 31 is electrically coupled to the motor 6 via a first lead wire 26, a second lead wire 27, and a third lead wire 28. Specifically, the first lead wire 26 is coupled to the first terminal 6a of the motor 6. The second lead wire 27 is coupled to the second terminal 6b of the motor 6. The third lead wire 28 is coupled to the third terminal 6c of the motor 6.

The drive circuit 31 generates three-phase voltages (i.e., three-phase power) from the battery voltage. The drive circuit 31 supplies the generated three-phase voltages to the motor 6 via the first through third lead wires 26 through 28, respectively. Hereinafter, a current supplied to the first terminal 6a via the first lead wire 26 is referred to as U-phase current, a current supplied to the second terminal 6b via the second lead wire 27 is referred to as V-phase current, and a current supplied to the third terminal 6c via the third lead wire 28 is referred to as W-phase current. Similarly, the voltage at the first terminal 6a is referred to as U-phase voltage, the voltage at the second terminal 6b is referred to as V-phase voltage, and the voltage at the third terminal 6c is referred to as W-phase voltage.

The drive circuit 31 of this first embodiment is a three-phase bridge circuit (or a three-phase full-bridge circuit); however, the drive circuit 31 is not limited thereto.

The drive circuit 31 includes first through third current paths Lp1 through Lp3. The first through third current paths Lp1 through Lp3 each correspond to a so-called upper arm. The first through third current paths Lp1 through Lp3 electrically couple the power line Lp to the first through third terminals 6a through 6c, respectively, of the motor 6.

The drive circuit 31 includes fourth through sixth current paths Lp4 through Lp6. The fourth through sixth current paths Lp4 through Lp6 each correspond to a so-called lower arm. The fourth through sixth current paths Lp4 through Lp6 electrically couple the ground line Ln to the first through third terminals 6a through 6c, respectively, of the motor 6.

The drive circuit 31 includes a first switch Q1 provided in the first current path Lp1, a second switch Q2 provided in the second current path Lp2, a third switch Q3 provided in the third current path Lp3, a fourth switch Q4 provided in the fourth current path Lp4, a fifth switch Q5 provided in the fifth current path Lp5, and a sixth switch Q6 provided in the sixth current path Lp6.

Each of the first through third switches Q1 through Q3 (i) is included in the corresponding upper arm and (ii) functions as a so-called high-side switch. Each of the fourth through sixth switches Q4 through Q6 (i) is included in the corresponding lower arm and (ii) functions as a so-called low-side switch. The first through third current paths Lp1 through Lp3 are established or interrupted by the first through third switches Q1 through Q3, respectively. The fourth through sixth current paths Lp4 through Lp6 are established or interrupted by the fourth through sixth switches Q4 through Q6, respectively.

Each of the first through sixth switches Q1 through Q6 is a semiconductor switch. In this first embodiment, each of the first through sixth switches Q1 through Q6 is in the form of an n-channel metal-oxide-semiconductor field-effect transistor (MOSFET). However, each of the first through sixth switches Q1 through Q6 may be other type of semiconductor switch, such as a bipolar junction transistor (BJT), an insulated-gate bipolar transistor (IGBT), or a gallium nitride field-effect transistor (GaN-FET).

The first switch Q1 receives a first drive signal UH from the control circuit 30 and is turned on or off according to the first drive signal UH. The second switch Q2 receives a second drive signal VH from the control circuit 30 and is turned on or off according to the second drive signal VH. The third switch Q3 receives a third drive signal WH from the control circuit 30 and is turned on or off according to the third drive signal WH. The fourth switch Q4 receives a fourth drive signal UL from the control circuit 30 and is turned on or off according to the fourth drive signal UL. The fifth switch Q5 receives a fifth drive signal VL from the control circuit 30 and is turned on or off according to the fifth drive signal VL. The sixth switch Q6 receives a sixth drive signal WL from the control circuit 30 and is turned on or off according to the sixth drive signal WL. In this first embodiment, each of the first through sixth drive signals UH, VH, WH, UL, VL, and WL may be a pulse-width modulation signal.

When the motor 6 is driven, basically, one of the high-side switches and one of the low-side switches are turned on. This causes a current to flow from a positive electrode of the battery pack 15 to a negative electrode thereof via the corresponding high-side switch, the motor 6, and the corresponding low-side switch (this current is hereinafter referred to as “bus current”), thereby driving the motor 6 to rotate. More specifically, there may be a case where one high-side switch and two low-side switches are simultaneously turned on. The two low-side switches are located in two legs different from a leg in which the one high-side switch is located. Alternatively, there may be a case where two high-side switches and one low-side switch are simultaneously turned on. The one low-side switch is located in a leg different from two legs in which the two high-side switches are located.

The electric work machine 1 includes a first current detection circuit 36 provided in the first lead wire 26. The first current detection circuit 36 detects a U-phase current value. The U-phase current value represents the magnitude of the U-phase current. Specifically, the first current detection circuit 36 outputs a U-phase current detection signal Siu corresponding to the U-phase current value. The U-phase current detection signal Siu is supplied to the control circuit 30.

The electric work machine 1 includes a second current detection circuit 37 provided in the second lead wire 27. The second current detection circuit 37 detects a V-phase current value. The V-phase current value represents the magnitude of the V-phase current. Specifically, the second current detection circuit 37 outputs a V-phase current detection signal Siv corresponding to the V-phase current value. The V-phase current detection signal Siv is supplied to the control circuit 30.

The electric work machine 1 includes a third current detection circuit 38 provided in the third lead wire 28. The third current detection circuit 38 detects a W-phase current value. The W-phase current value represents the magnitude of the W-phase current. Specifically, the third current detection circuit 38 outputs a W-phase current detection signal Siw corresponding to the W-phase current value. The W-phase current detection signal Siw is supplied to the control circuit 30. At least one of the first through third current detection circuits 36 through 38 may be disposed within the drive circuit 31.

The first through third current detection circuits 36 through 38 are provided to detect the U-phase current value, the V-phase current value, and the W-phase current value, respectively. The U-phase current value, the V-phase current value, and the W-phase current value may be detected by any suitable method. For example, the first through third current detection circuits 36 through 38 may be provided at locations other than the first through third lead wires 26 through 28, respectively. Specifically, the first through third current detection circuits 36 through 38 may be provided in the fourth through sixth current paths Lp4 through Lp6, respectively. Alternatively, one or two of the first through third current detection circuits 36 through 38 may be omitted. As an example, in a case where the third current detection circuit 38 is omitted, the control circuit 30 is capable of detecting (or estimating) the W-phase current value based on the U-phase current detection signal Siu and/or the V-phase current detection signal Siv. As another example, in a case where the second and third current detection circuits 37 and 38 are omitted, the control circuit 30 is capable of detecting (or estimating) the V-phase current value and the W-phase current value based on the U-phase current detection signal Siu. Alternatively, for example, the first through third current detection circuits 36 through 38 may all be omitted. In this case, the control circuit 30 may calculate the U-phase current value, the V-phase current value, and the W-phase current value based on a bus current value (described below).

The controller 13 includes a bus current detection circuit 33. The bus current detection circuit 33 is provided in a current path through which the bus current flows. In this first embodiment, the bus current detection circuit 33 is provided in the ground line Ln within the controller 13, and more specifically, in a current path between the drive circuit 31 and the ground. The bus current detection circuit 33 detects the bus current value. The bus current value represents the magnitude of the bus current. Specifically, the bus current detection circuit 33 outputs a bus current detection signal Sib corresponding to the bus current value. The bus current detection signal Sib is supplied to the control circuit 30. Each of the first through third current detection circuits 36 through 38 and the bus current detection circuit 33 may have any structure capable of detecting the corresponding current value. Each of the first through third current detection circuits 36 through 38 and the bus current detection circuit 33 may, for example, (i) include a resistor (a so-called shunt resistor) configured to allow the corresponding current to flow therethrough and (ii) be configured to output the bus current detection signal Sib based on the voltage across the resistor.

The controller 13 includes a battery voltage detection circuit 34. The battery voltage detection circuit 34 is coupled to the power line Lp to receive the battery voltage via the power line Lp. The battery voltage detection circuit 34 detects a battery voltage value. The battery voltage value represents the magnitude of the battery voltage. Specifically, the battery voltage detection circuit 34 outputs a battery voltage detection signal Svb corresponding to the battery voltage value. The battery voltage detection signal Svb is supplied to the control circuit 30.

The controller 13 includes a first temperature detection circuit 39. The first temperature detection circuit 39 is provided within the drive circuit 31 or in the vicinity thereof to detect a drive circuit temperature. The drive circuit temperature is a temperature of the drive circuit 31. The first temperature detection circuit 39 includes a first temperature sensor (not shown). The first temperature sensor is a thermistor, for example. The first temperature sensor outputs a first temperature detection signal Std corresponding to a temperature around the first temperature sensor (i.e., corresponding to the drive circuit temperature). The first temperature detection signal Std is supplied to the control circuit 30.

The electric work machine 1 includes a second temperature detection circuit 23. The second temperature detection circuit 23 is provided within the motor 6 or in the vicinity thereof to detect a motor temperature. The motor temperature is a temperature of the motor 6. The second temperature detection circuit 23 includes a second temperature sensor (not shown). The second temperature sensor is a thermistor, for example. The second temperature sensor outputs a second temperature detection signal Stm corresponding to a temperature around the second temperature sensor (i.e., corresponding to the motor temperature). The second temperature detection signal Stm is supplied to the control circuit 30.

The electric work machine 1 includes a tool-type detector 29. The tool-type detector 29 outputs tool information Sto. The tool information Sto indicates the type of the end tool 9 attached to the electric work machine 1 (more specifically, to the guide bar 8). The tool information Sto is an example of the “attached device information” referred to in the Overview of Embodiments. The tool information Sto is supplied to the control circuit 30. The control circuit 30 is capable of identifying the type of the end tool 9 based on the tool information Sto. In this first embodiment, the types of the end tool 9 include a first-type tool and a second-type tool. By way of example, the first-type tool (i) is comparatively heavy and (ii) may require high torque (e.g., a specified torque or higher) to be driven. The second-type tool (i) is comparatively light and (ii) does not require high torque to be driven.

The control circuit 30 may be capable of identifying the type of the end tool 9 without requiring the tool-type detector 29. The control circuit 30 may be capable of identifying the type of the end tool 9 based on, for example, the behavior of the motor 6. Examples of the behavior of the motor 6 include (i) a change in the current flowing through the motor 6 (e.g., the U-phase current, the V-phase current, the W-phase current, and/or the bus current), (ii) a change in the voltage applied to the motor 6, and/or (iii) a change in the load torque applied to the motor 6. For example, in a case where the magnitude of the current or the load torque to the motor 6 increases sharply (e.g., at or above a specified rate of increase) at the start of driving of the motor 6, the control circuit 30 may determine that the end tool 9 attached is the first-type tool. On the other hand, in a case where the magnitude of the current to the motor 6 increases moderately (e.g., at a rate less than the specified rate of increase) at the start of driving, the control circuit 30 may determine that the end tool 9 attached is the second-type tool.

The electric work machine 1 includes a trigger detection circuit 22, which is mechanically coupled to the trigger 10. The trigger detection circuit 22 outputs a first trigger signal TR1 and a second trigger signal TR2 each corresponding to a state of the trigger 10. The first trigger signal TR1 (i) is a binary signal and (ii) indicates whether the trigger 10 is manually operated. For example, the first trigger signal TR1 is at a low level while the trigger 10 is not manually operated, and the first trigger signal TR1 is at a high level while the trigger 10 is manually operated. The second trigger signal TR2 (i) is an analog signal and (ii) indicates a movement amount (i.e., a pull amount) of the trigger 10 from an initial position thereof. The second trigger signal TR2 may be output while the trigger 10 is manually operated.

The first and second trigger signals TR1 and TR2 are supplied to the control circuit 30. Based on the first and second trigger signals TR1 and TR2, the control circuit 30 is capable of determining whether the trigger 10 is turned on (i.e., manually operated) and the movement amount of the trigger 10.

The mode setting switch 12a and the indicator 12b described above are electrically coupled to the control circuit 30. The control circuit 30 receives the operation signal Sms from the mode setting switch 12a. Based on the presence or absence of the operation signal Sms, the control circuit 30 is capable of determining whether the mode setting switch 12a is pressed.

In this first embodiment, attaching the battery pack 15 to the battery port 3 does not immediately result in generation of the power-supply voltage Vc. After the attachment of the battery pack 15, the power-supply voltage Vc is generated in response to a long press of the mode setting switch 12a, whereby the control circuit 30 is activated. The long press refers to, for example, continuously pressing the mode setting switch 12a for a first specified period (e.g., 3 seconds) or longer.

The control circuit 30 sets an operation mode of the electric work machine 1 to one of a first mode and a second mode.

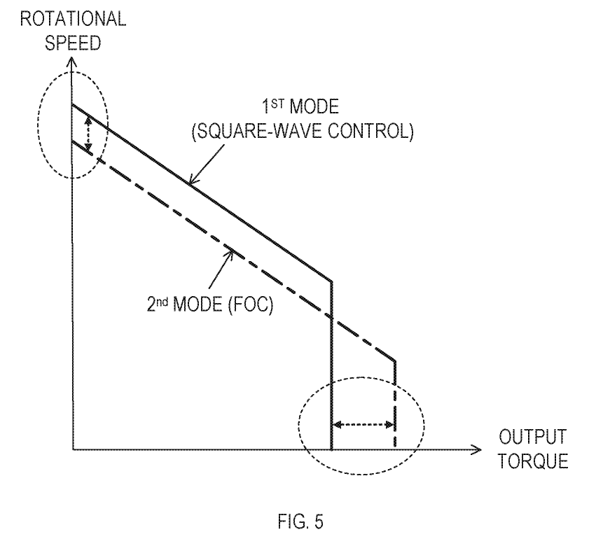

As schematically shown in FIG. 5, the first mode is an operation mode in which the rotational speed of the motor 6 takes priority over an output torque of the motor 6. More specifically, the first mode is an operation mode in which rotating the motor 6 at higher speed takes priority over rotating the motor 6 while causing it to output a higher output torque. In the first mode, it is possible to rotate the motor 6 at higher speed than in the second mode. Specifically, as illustrated in FIG. 5, a maximum value of the rotational speed in the first mode is greater than that in the second mode. The first mode may be referred to as high-speed mode or quiet mode, for example.

On the other hand, the second mode is an operation mode in which the output torque takes priority over the rotational speed. More specifically, the second mode is an operation mode in which rotating the motor 6 at higher output torque takes priority over rotating the motor 6 at higher speed. In the second mode, it is possible to rotate the motor 6 at higher output torque than in the first mode. Specifically, as illustrated in FIG. 5, a maximum value of the output torque in the second mode is greater than that in the first mode. The second mode may be referred to as high-torque mode or high-power mode, for example.

The below-described rotational speed-torque characteristics of the electric work machines in the second through sixth embodiments each exhibit a trend (or operational characteristics) that is (i) the same as that shown in FIG. 5, or (ii) similar to that shown in FIG. 5, or (iii) at least partially the same as that shown in FIG. 5. That is, in the second through sixth embodiments as well, the first mode is an operation mode in which priority is given to the rotational speed, and the second mode is an operation mode in which priority is given to the output torque, as in this first embodiment. For example, in a torque region where the output torque is comparatively low, the rotational speed in the first mode may be higher than that in the second mode. On the other hand, for example, in a speed region where the rotational speed is comparatively low, the output torque in the second mode may be higher than that in the first mode.

The control circuit 30 sets a switching mode for switching the operation mode to one of a manual mode and an automatic mode. In the manual mode, the operation mode is switched by the user’s manual operation. In the automatic mode, the operation mode is switched automatically without requiring the user’s manual operation.

Upon being activated, the control circuit 30 performs initial setting of the operation mode and the switching mode. In this first embodiment, for example, the operation mode is initially set to the first mode, and the switching mode is initially set to the manual mode.

Subsequently, each time a manual/automatic switching operation is performed on the mode setting switch 12a, the control circuit 30 switches the switching mode. For example, when the manual/automatic switching operation is performed while the switching mode is set to the manual mode, the control circuit 30 switches the switching mode to the automatic mode. When the manual/automatic switching operation is performed while the switching mode is set to the automatic mode, the control circuit 30 switches the switching mode to the manual mode.

While the switching mode is set to the manual mode, the control circuit 30 sets the operation mode in response to performance of a first manual operation or a second manual operation on the mode setting switch 12a. Specifically, the control circuit 30 sets the operation mode to the first mode in response to the first manual operation being performed on the mode setting switch 12a. When the first manual operation is performed while the operation mode is set to the second mode, the operation mode is switched to the first mode. The control circuit 30 sets the operation mode to the second mode in response to the second manual operation being performed on the mode setting switch 12a. When the second manual operation is performed while the operation mode is set to the first mode, the operation mode is switched to the second mode.

The first manual operation and the second manual operation may each be any operation. In this first embodiment, the first manual operation and the second manual operation are both involve brief press of the mode setting switch 12a. In the description below, an “operation-mode switching operation” includes both the first manual operation and the second manual operation, thus being a collective term therefor.

The brief press refers to pressing the mode setting switch 12a and then releasing the pressed state of the mode setting switch 12a before a lapse of a second specified period (e.g., 0.5 seconds). The second specified period is shorter than the first specified period.

The manual/automatic switching operation may be any suitable operation. Examples of the manual/automatic switching operation may include briefly pressing the mode setting switch 12a twice in quick succession. In this case, it may be required that a time interval from the end of the first brief press to the start of the second brief press be equal to or less than a time interval upper limit. The time interval upper limit may be (i) greater than zero, (ii) set as appropriate in advance, and (iii) for example, 1 second.

At the point when the mode setting switch 12a is briefly pressed once, the control circuit 30 cannot yet determine whether the operation-mode switching operation has been performed or the manual/automatic switching operation has been performed. The control circuit 30 determines that the operation-mode switching operation has been performed if, after the brief press of the mode setting switch 12a, the mode setting switch 12a is not operated again before a lapse of the time interval upper limit from the end of the brief press.

The operation mode and the switching mode may be settable with respective separate manual switches. For example, in addition to the mode setting switch 12a, another manual switch may be further provided. In this case, the switching mode may be switched in response to a manual operation (e.g., a single brief press) of said another switch and the operation mode may be switched in response to a manual operation (e.g., a single brief press) of the mode setting switch 12a.

The control circuit 30 controls the indicator 12b (more specifically, the LED in this first embodiment) according to the state of the electric work machine 1.

In a case where the switching mode is set to the manual mode and the operation mode is set to the first mode, the control circuit 30 causes the indicator 12b to light up in a first manner. The first manner may be, for example, causing the LED to light up in a first color (e.g., green).

In a case where the switching mode is set to the manual mode and the operation mode is set to the second mode, the control circuit 30 causes the indicator 12b to light up in a second manner. The second manner may be, for example, causing the LED to light up in a second color (e.g., yellow).

In a case where the switching mode is set to the automatic mode and the operation mode is set to the first mode, the control circuit 30 causes the indicator 12b to light up in a third manner. The third manner maybe, for example, causing the LED to blink in the first color.

In a case where the switching mode is set to the automatic mode and the operation mode is set to the second mode, the control circuit 30 causes the indicator 12b to light up in a fourth manner. The fourth manner may be, for example, causing the LED to blink in the second color.

The control circuit 30 receives the first through third Hall signals Hu, Hv, and Hw from the position signal output circuit 21. As described above, the phases of the first through third Hall signals Hu, Hv, and Hw are offset from each other by 120 degrees in electrical angle. Thus, each time the rotor 19 rotates by 60 degrees in electrical angle, the logical value of any one of the first through third Hall signals Hu, Hv, and Hw changes. Based on such change in the logical value every 60 degrees, the control circuit 30 detects a rotational position (i.e., a rotation angle) θ and an actual rotational speed ω_m of the motor 6.

The control circuit 30 further receives the first temperature detection signal Std and the second temperature detection signal Stm. The control circuit 30 further receives the U-phase current detection signal Siu, the V-phase current detection signal Siv, the W-phase current detection signal Siw, the bus current detection signal Sib, and the battery voltage detection signal Svb.

The control circuit 30 is configured to be capable of communication (e.g., serial communication) with the battery pack 15. The control circuit 30 may be capable of wired communication with the battery pack 15 or wireless communication therewith. The wired communication may be enabled while the battery pack 15 is attached to the battery port 3.

The control circuit 30 is capable of acquiring battery pack information Infb from the battery pack 15 through the communication therewith. The control circuit 30 may acquire the battery pack information Infb by requesting the battery pack information Infb from the battery pack 15, as necessary. Alternatively, a configuration may be employed in which the battery pack 15 repeatedly transmits the battery pack information Infb to the control circuit 30 regularly or irregularly and the control circuit 30 receives the transmitted battery pack information Infb.

The battery pack information Infb may include various pieces of information regarding the battery pack 15. In this first embodiment, the battery pack information Infb includes battery information and model information. The battery information and the model information are each an example of the “attached device information” referred to in the Overview of Embodiments.

### The model information indicates a model of the battery pack 15.

The battery information directly or indirectly indicates an operating state and/or performance of the battery 15a. The battery information includes the magnitude of the internal resistance of the battery 15a and the temperature of the battery 15a (hereinafter referred to as “battery temperature”). The battery information may include various parameters corresponding to the performance of the battery 15a. The various parameters may include, for example, various protection thresholds. The various protection thresholds are used to protect the battery 15a, in the battery pack 15. The various protection thresholds may include, for example, an overcurrent threshold and an overheating threshold. The battery pack 15 may be configured to forcibly cut off discharge from the battery 15a in response to the magnitude of discharge current from the battery 15a exceeding the overcurrent threshold. The battery pack 15 may be configured to forcibly cut off discharge from the battery 15a in response to the temperature of the battery 15a exceeding the overheating threshold. The various protection thresholds are determined according to the performance of the battery 15a. For example, the more power the battery 15a is capable of supplying, the higher values/value the overcurrent threshold and/or the overheating threshold may be set to.

### 2-1-3. Functions of Control Circuit

The control circuit 30 of this first embodiment controls the motor 6 (directly, controls the drive circuit 31) according to one of a first control scheme and a second control scheme. When the operation mode is set to the first mode, the control circuit 30 controls the motor 6 according to the first control scheme. When the operation mode is set to the second mode, the control circuit 30 controls the motor 6 according to the second control scheme.

In this first embodiment, the first control scheme includes square-wave control, and the second control scheme includes field-oriented control (FOC). In other words, the first control scheme is a control scheme that does not employ FOC. FOC in the second control scheme is an example of the “second FOC” referred to in the Overview of Embodiments.

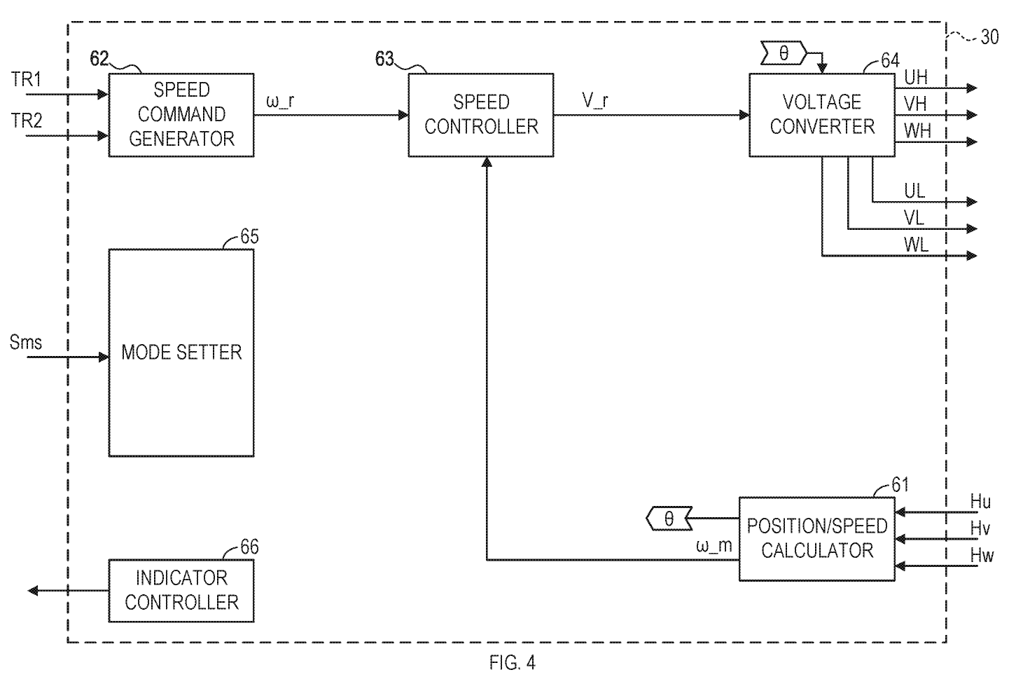

When the operation mode is set to the first mode, the control circuit 30 functions as shown in FIG. 4, thereby performing the square-wave control.

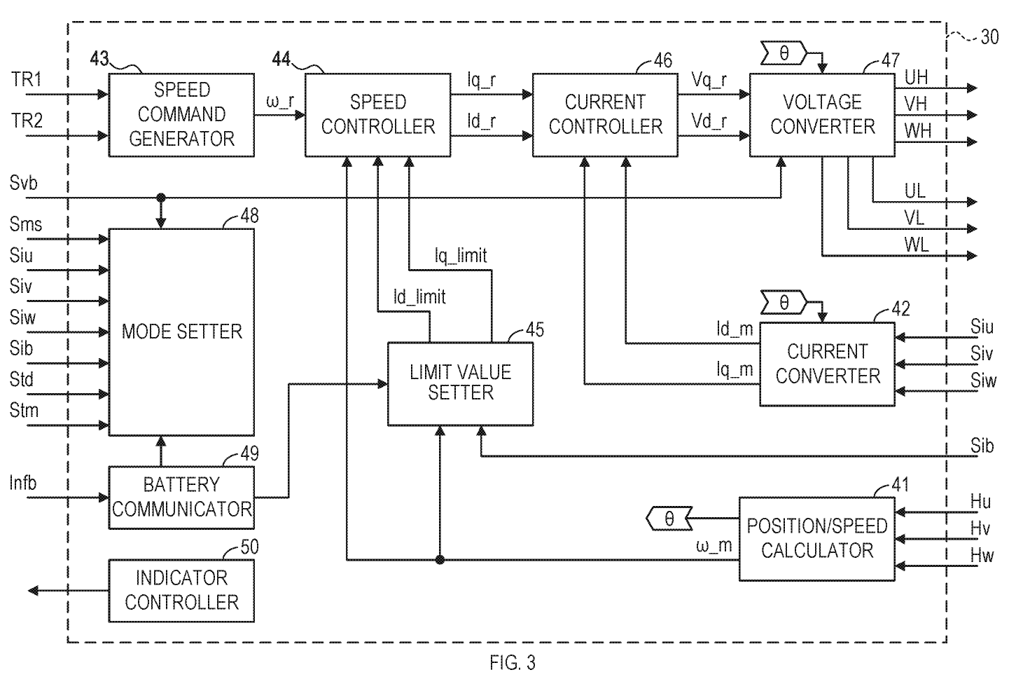

When the operation mode is set to the second mode, the control circuit 30 functions as shown in FIG. 3, thereby performing FOC.

Hereinafter, the functions of the control circuit 30 in each of the first mode and the second mode will be described in order with reference to FIGS. 3 and 4.

### 2-1-3-1. Functions of Control Circuit in Second Mode

When the operation mode is set to the second mode, the control circuit 30 performs FOC. Specifically, as shown in FIG. 3, the control circuit 30 in the second mode has functions as a position/speed calculator 41, a current converter 42, a speed command generator 43, a speed controller 44, a limit value setter 45, a current controller 46, a voltage converter 47, a mode setter 48, a battery communicator 49, and an indicator controller 50. These functions are implemented, for example, but not limited to, by the processor 30a executing a computer program stored in the memory 30b.

As another example, at least one function of the position/speed calculator 41, the current converter 42, the speed command generator 43, the speed controller 44, the limit value setter 45, the current controller 46, the voltage converter 47, the mode setter 48, the battery communicator 49, and the indicator controller 50 may be implemented by hardware (e.g., a dedicated electronic circuit; more specifically, the above-described logic circuit or hardwired logic connection, for example) instead of software. That is, corresponding hardware may be incorporated into the control circuit 30.

The position/speed calculator 41 receives the first through third Hall signals Hu, Hv, and Hw from the position signal output circuit 21 (see FIG. 2). Based on the first through third Hall signals Hu, Hv, and Hw, the position/speed calculator 41 calculates a rotation angle θ and the actual rotational speed ω_m of the rotor 19. The rotation angle θ indicates a rotational position (more specifically, an electrical angle) of the rotor 19. The actual rotational speed ω_m is a measured value of the actual rotational speed of the rotor 19. Specifically, the position/speed calculator 41 calculates the rotation angle θ and the actual rotational speed ω_m each time the logical value of any of the first through third Hall signals Hu, Hv, and Hw changes (i.e., each time the rotor 19 rotates by 60 degrees in electrical angle).

A method for calculating the rotation angle θ and the actual rotational speed ω_m based on the first through third Hall signals Hu, Hv, and Hw is not limited to a specific method, and a known method may be employed, for example. The position/speed calculator 41 outputs the calculated rotation angle θ to the current converter 42 and the voltage converter 47, and outputs the calculated actual rotational speed ω_m to the speed controller 44 and the limit value setter 45.

The current converter 42 receives the U-, V-, and W-phase current detection signals Siu, Siv, and Siw from the first through third current detection circuits 36, 37, and 38, respectively. The current converter 42 converts the U-phase current value, the V-phase current value, and the W-phase current value indicated respectively by the U-, V-, and W-phase current detection signals Siu, Siv, and Siw into a d-axis actual current value Id_m and a q-axis actual current value Iq_m. The d-axis actual current value Id_m corresponds to a d-axis current in a d-q reference frame. That is, the d-axis actual current value Id_m indicates a value of a d-axis current actually flowing through the motor 6. The q-axis actual current value Iq_m corresponds to a q-axis current in the d-q reference frame. That is, the q-axis actual current value Iq_m indicates a value of a q-axis current actually flowing through the motor 6.

In the d-q reference frame, each of the d-axis actual current value Id_m and the q-axis actual current value Iq_m is represented by a vector. Specifically, the d-axis actual current value Id_m is represented by a d-axis vector that (i) is along the d-axis and (ii) has a magnitude of Id_m. The q-axis actual current value Iq_m is represented by a q-axis vector that (i) is along the q-axis and (ii) has a magnitude of Iq_m. The starting point of the d-axis vector and the starting point of the q-axis vector correspond to the origin in the d-q reference frame.

The sum of the d-axis vector and the q-axis vector is referred to as “current vector”. The current converter 42 is capable of converting the U-phase current value, the V-phase current value, and the W-phase current value into the d-axis actual current value Id_m and the q-axis actual current value Iq_m by, for example, Clarke transformation and Park transformation. The current converter 42 outputs the d-axis actual current value Id_m and the q-axis actual current value Iq_m to the current controller 46.

The speed command generator 43 receives the first trigger signal TR1 and the second trigger signal TR2. The speed command generator 43 calculates a speed command value ω_r based on the first trigger signal TR1 and the second trigger signal TR2.

The speed command value ω_r is a command value for the rotational speed of the rotor 19. When the first trigger signal TR1 indicates that the trigger 10 is not manually operated, the speed command generator 43 calculates the speed command value ω_r as “0”. When the first trigger signal TR1 indicates that the trigger 10 is manually operated, the speed command generator 43 calculates the speed command value ω_r according to the pull amount of the trigger 10 indicated by the second trigger signal TR2. Specifically, the speed command generator 43 calculates the speed command value ω_r such that the speed command value ω_r increases as the pull amount increases. The speed command generator 43 outputs the calculated speed command value ω_r to the speed controller 44.

The speed controller 44 receives the speed command value ω_r and the actual rotational speed ω_m. The speed controller 44 further receives a d-axis current limit value Id_limit and a q-axis current limit value Iq_limit from the limit value setter 45.

The speed controller 44 calculates a d-axis current command value Id_r and a q-axis current command value Iq_r based on the speed command value ω_r and the actual rotational speed ω_m. Specifically, the speed controller 44 calculates the d-axis current command value Id_r and the q-axis current command value Iq_r by using, for example, PI control such that a difference between the speed command value ω_r and the actual rotational speed ω_m approaches zero. At this time, the speed controller 44 (i) calculates the d-axis current command value Id_r within a range not exceeding the d-axis current limit value Id_limit, and (ii) calculates the q-axis current command value Iq_r within a range not exceeding the q-axis current limit value Iq_limit. The speed controller 44 outputs the calculated d-axis current command value Id_r and q-axis current command value Iq_r to the current controller 46.

The limit value setter 45 receives the bus current detection signal Sib, the actual rotational speed ω_m, and the battery pack information Infb. Based on them, the limit value setter 45 sets the d-axis current limit value Id_limit and the q-axis current limit value Iq_limit.

FOC of this first embodiment may be performed in any one of a plurality of control modes. Examples of the control modes include an MTPA control mode, a field-weakening control mode, and a zero d-axis current control mode.

The MTPA control mode is a mode for performing MTPA control. The MTPA control is a type of FOC. The MTPA control is a control scheme for controlling the motor 6 such that a current vector (more specifically, the tip thereof) moves along an MTPA curve in the d-q reference frame. The MTPA curve is defined according to various characteristics of the motor 6.

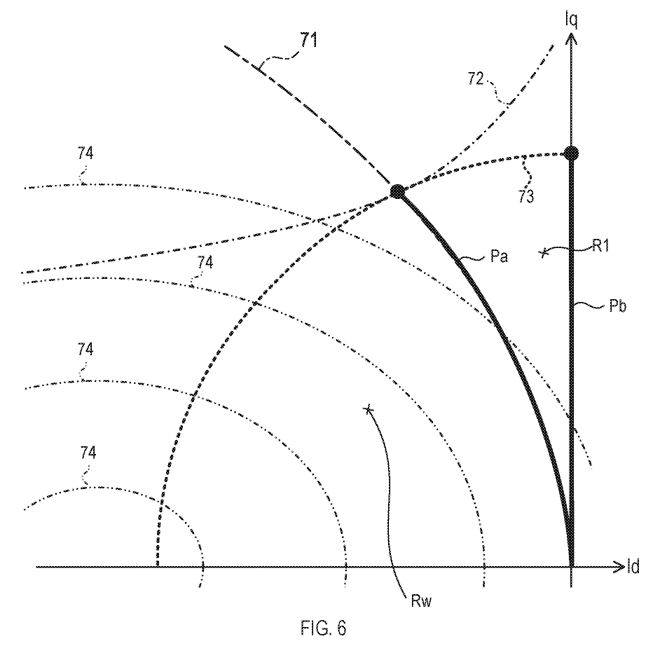

FIG. 6 illustrates an MTPA curve 71 of the motor 6. FIG. 6 further illustrates a constant torque curve 72, a constant current circle 73, and a plurality of voltage limit ellipses 74 in the motor 6. While a plurality of the constant torque curves 72 and a plurality of the constant current circles 73 may be included in the motor 6, FIG. 6 illustrates only a specific one of each. In FIGS. 6, 12, and 13, the horizontal axis represents the d-axis, and the vertical axis represents the q-axis.

In the MTPA control mode, the current vector may be controlled to move within a first range Pa on the MTPA curve 71, for example. The first range Pa is a range, on the MTPA curve 71, from the origin to an intersection with the constant current circle 73.

The field-weakening control mode is a mode for performing field-weakening control. The field-weakening control is a type of FOC. The field-weakening control is a control scheme that increases a negative d-axis current of the current vector as compared with the MTPA control to thereby reduce field flux.

More specifically, the field-weakening control includes controlling the motor 6 such that the current vector (more specifically, the tip thereof) moves within a field-weakening region Rw in the d-q reference frame. The field-weakening region Rw is an example of the “first region” referred to in the Overview of Embodiments. The field-weakening region Rw is a region (i) not including the MTPA curve 71 and (ii) on a d-axis negative side relative to the MTPA curve 71.

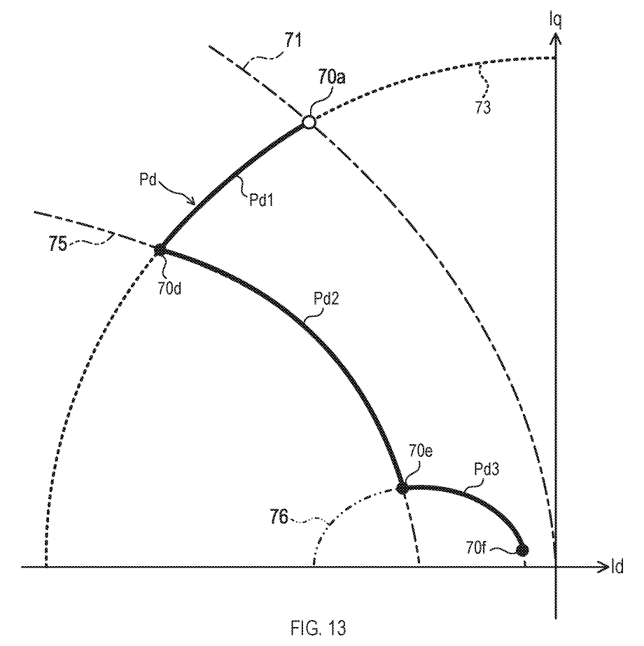

The field-weakening region Rw may be set in any manner. The field-weakening region Rw may be, for example, a region that is (i) on the d-axis negative side relative to the MTPA curve 71 and (ii) within a specific constant current circle 73. The field-weakening region Rw may be, for example, a region (i) that is on the d-axis negative side relative to the MTPA curve 71, (ii) that is within the specific constant current circle 73, and (iii) from which an inside of a specific voltage limit ellipse 74 is excluded. The field-weakening region Rw includes an outer periphery of the specific voltage limit ellipse 74. As in the example shown in FIG. 13 described below, in a case where an MTPV curve 75 is present within the specific constant current circle 73, a region on the d-axis negative side relative to the MTPV curve 75 may be excluded from the field-weakening region Rw.

The zero d-axis current control mode is a mode for performing the zero d-axis current control. The zero d-axis current control is a type of FOC. The zero d-axis current control is a control scheme for controlling the motor 6 such that the current vector (more specifically, the tip thereof) moves along the q-axis in the d-q reference frame (i.e., such that a d-axis component is not generated). In the zero d-axis current control mode, the current vector may be controlled to move within a second range Pb on the q-axis, for example. The second range Pb is a range, on the q-axis, from the origin to an intersection with the specific constant current circle 73. The zero d-axis current control may be referred to as “Id = 0 control”.

The plurality of control modes may further include another control mode. Such another control mode may be, for example, a mode for controlling the motor 6 such that the current vector (more specifically, the tip thereof) moves within a first region R1. The first region R1 is a region surrounded by the MTPA curve 71, the q-axis, and the specific constant current circle 73. The first region R1 may or may not include the MTPA curve 71 and/or the q-axis.

The speed controller 44 calculates the d-axis current command value Id_r and the q-axis current command value Iq_r corresponding to a determined control mode.

The current controller 46 receives the d-axis current command value Id_r and the q-axis current command value Iq_r from the speed controller 44. The current controller 46 further receives the d-axis actual current value Id_m and the q-axis actual current value Iq_m from the current converter 42.

The current controller 46 calculates a d-axis voltage command value Vd_r and a q-axis voltage command value Vq_r based on the d-axis current command value Id_r, the q-axis current command value Iq_r, the d-axis actual current value Id_m, and the q-axis actual current value Iq_m. The current controller 46 may calculate the d-axis voltage command value Vd_r and the q-axis voltage command value Vq_r by using, for example, PI control. Specifically, the current controller 46 may calculate the d-axis voltage command value Vd_r and the q-axis voltage command value Vq_r such that a difference between the d-axis current command value Id_r and the d-axis actual current value Id_m, and a difference between the q-axis current command value Iq_r and the q-axis actual current value Iq_m, each approach zero.

The voltage converter 47 receives the d-axis voltage command value Vd_r and the q-axis voltage command value Vq_r from the current controller 46. The voltage converter 47 further receives the rotation angle θ. The voltage converter 47 calculates three-phase voltage command values based on the d-axis voltage command value Vd_r, the q-axis voltage command value Vq_r, and the rotation angle θ.

The voltage converter 47 converts the d-axis voltage command value Vd_r and the q-axis voltage command value Vq_r into the three-phase voltage command values by, for example, inverse Clarke transformation and inverse Park transformation. The voltage converter 47 generates the first through sixth drive signals UH, VH, WH, UL, VL, and WL based on the calculated three-phase voltage command values, and outputs these drive signals to the drive circuit 31.

The voltage converter 47 further receives a battery voltage detection signal Svb. The voltage converter 47 acquires a battery voltage value from the battery voltage detection signal Svb. The voltage converter 47 is capable of overmodulation control based on the acquired battery voltage value. The overmodulation control will be described in detail in the third embodiment described below. Although the overmodulation control is performed in the first mode in the third embodiment, in this first embodiment, the overmodulation control may be performed in the second mode.

The mode setter 48 receives the U-phase current detection signal Siu, the V-phase current detection signal Siv, the W-phase current detection signal Siw, the bus current detection signal Sib, the battery voltage detection signal Svb, the first temperature detection signal Std, the second temperature detection signal Stm, the operation signal Sms, the battery pack information Infb, and the tool information Sto. Based on these various signals and/or various pieces of information, the mode setter 48 sets the operation mode and the switching mode.

The battery communicator 49 is responsible for processing related to communication with the battery pack 15. The battery communicator 49 acquires the battery pack information Infb from the battery pack 15. The battery communicator 49 outputs the acquired battery pack information Infb to the mode setter 48 and the limit value setter 45.

The indicator controller 50 controls an operation of the indicator 12b.

### 2-1-3-2. Functions of Control Circuit in First Mode

When the operation mode is set to the first mode, the control circuit 30 performs the square-wave control. Specifically, as shown in FIG. 4, the control circuit 30 in the first mode functions as a position/speed calculator 61, a speed command generator 62, a speed controller 63, a voltage converter 64, a mode setter 65, and an indicator controller 66. These functions are implemented, for example, but not limited to, by the processor 30a executing a computer program stored in the memory 30b.

As another example, at least one function of the position/speed calculator 61, the speed command generator 62, the speed controller 63, the voltage converter 64, the mode setter 65, and the indicator controller 66 may be implemented by hardware (e.g., a dedicated electronic circuit; more specifically, the above-described logic circuit or hardwired logic connection, for example) instead of software. That is, corresponding hardware may be incorporated into the control circuit 30.

The position/speed calculator 61 is configured similarly to the position/speed calculator 41 of the first embodiment, and calculates the rotation angle θ and the actual rotational speed ω_m similarly to the position/speed calculator 41. The position/speed calculator 61 outputs the calculated rotation angle θ to the voltage converter 64, and outputs the calculated actual rotational speed ω_m to the speed controller 63.

The speed command generator 62 functions similarly to the speed command generator 43 in FIG. 3 and calculates the speed command value ω_r.

The speed controller 63 receives the speed command value ω_r and the actual rotational speed ω_m. Based on the speed command value ω_r and the actual rotational speed ω_m, the speed controller 63 calculates a voltage command value V_r. Specifically, the speed controller 63 calculates the voltage command value V_r by using, for example, PI control such that the difference between the speed command value ω_r and the actual rotational speed ω_m approaches zero. The voltage command value V_r of this first embodiment indicates a duty ratio. The speed controller 63 outputs the calculated voltage command value V_r to the voltage converter 64.

The voltage converter 64 receives the voltage command value V_r and the rotation angle θ. Based on the voltage command value V_r and the rotation angle θ, the voltage converter 64 generates the first through sixth drive signals UH, VH, WH, UL, VL, and WL, and outputs these drive signals to the drive circuit 31.

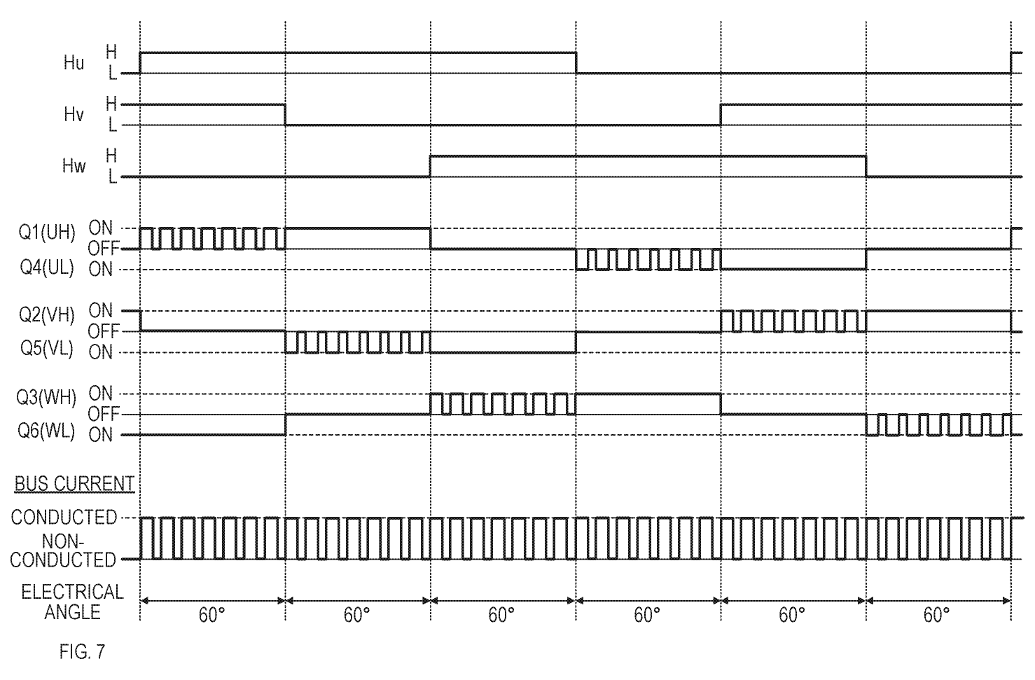

FIG. 7 shows a first operation example of the electric work machine 1 when the square-wave control is performed. As shown in FIG. 7, each time the rotor 19 rotates by 60 degrees in electrical angle, an edge transition of the first through third Hall signals Hu, Hv, and Hw occurs. The edge transition refers to a change in the logical value of any of the first through third Hall signals Hu, Hv, and Hw.

Each time the edge transition occurs, the control circuit 30 switches a conducting pair (also referred to as a drive pair) according to the rotation angle θ at that time. The conducting pair is a combination of one of the three high-side switches Q1 through Q3 to be turned on and one of the three low-side switches Q4 through Q6 to be turned on.

Each of the first through sixth switches Q1 through Q6 is driven during a period of a specified conduction angle in response to being set as the conducting pair. “Being driven” means being continuously kept on or being intermittently turned on (i.e., a state in which on and off are repeated). The conduction angle is, for example, 120 degrees in electrical angle. FIG. 7 shows an example in which each of the first through sixth switches Q1 through Q6 is intermittently driven during a first-half period of the conduction angle and is continuously driven during a second-half period thereof. During the period in which the switch is intermittently driven, on and off are periodically repeated according to the above-mentioned duty ratio. Specifically, each of the first through sixth switches Q1 through Q6 is constantly on when the duty ratio is 100%, and an on-period within one cycle decreases as the duty ratio becomes lower than 100%. Each of the first through sixth switches Q1 through Q6 may be intermittently driven also during the second-half period of the conduction angle.

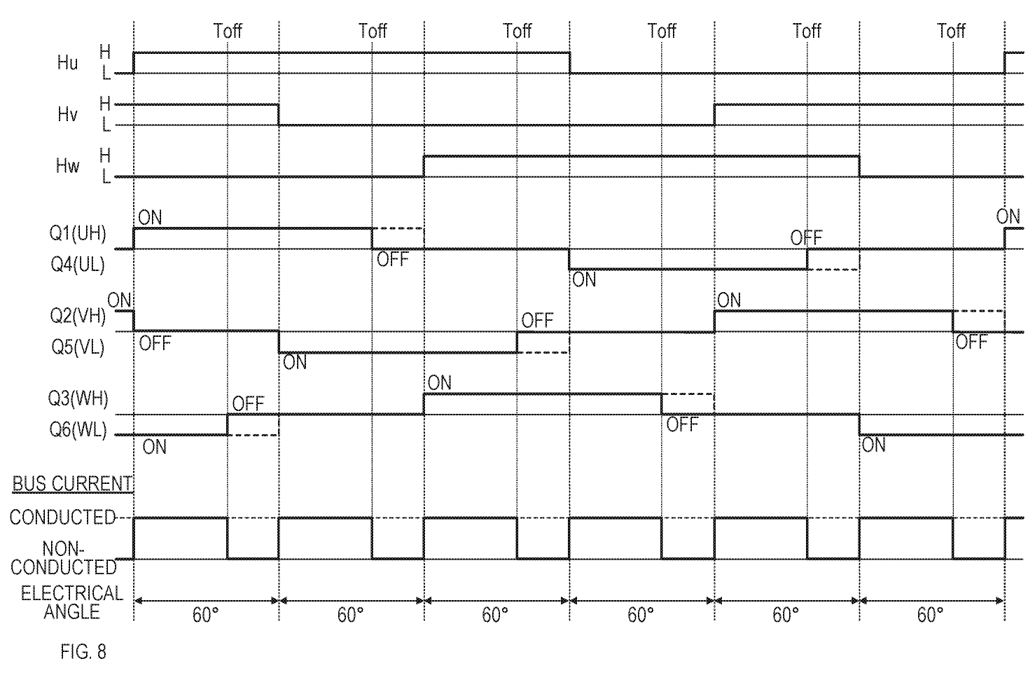

In response to the drive circuit 31 being driven in this manner, a square-wave voltage is applied from the drive circuit 31 to each of the first through third terminals 6a, 6b, and 6c of the motor 6. This causes the bus current to also vary periodically as schematically illustrated in FIG. 7. In FIG. 7, “conducted” means that the bus current is flowing, and “non-conducted” means that the bus current is not flowing. The same applies to FIG. 8.

FIG. 8 shows a second operation example of the electric work machine 1 when the square-wave control is performed. In the second operation example as well, each time the edge transition occurs, the control circuit 30 switches the conducting pair according to the rotation angle θ at that time, similarly to the first operation example. Each of the first through sixth switches Q1 through Q6 is driven during the period of the conduction angle in response to being set as the conducting pair.

The second operation example differs from the first operation example in that (i) each of the first through sixth switches Q1 through Q6 is continuously driven during the period of the conduction angle and (ii) conduction angle control and/or lead angle control are/is performed.

It can be easily understood from FIG. 8 (and from comparison with FIG. 7) that each of the first through sixth switches Q1 through Q6 is continuously driven during the period of the conduction angle.

The conduction angle control is to variably set the conduction angle according to an operating state of the motor 6. More specifically, the conduction angle control may include, for example, controlling the conduction angle such that the actual rotational speed ω_m matches the speed command value ω_r. Therefore, in the second operation example, the voltage command value V_r from the speed controller 63 may indicate the conduction angle. Then, the voltage converter 64 may sequentially drive the conducting pair according to the conduction angle indicated by the voltage command value V_r.

In the conduction angle control, for example, the conduction angle may be controlled within a range of an electrical angle equal to or less than a maximum conduction angle. The maximum conduction angle may be determined in any manner. The maximum conduction angle may be 180 degrees, for example. In the conduction angle control, the conduction angle may be set such that, for example, the conduction angle increases (i.e., approaches the maximum conduction angle) as a difference between the actual rotational speed ω_m and the speed command value ω_r increases.

FIG. 8 shows an example in which the conduction angle control is performed. Specifically, FIG. 8 shows an example in which each switch is turned off at an off-timing Toff, which is before the rotor 19 rotates by 120 degrees in electrical angle after the switch is turned on.

The lead angle control includes advancing an on-timing of each of the first through sixth switches Q1 through Q6 by a time corresponding to a lead angle from a specified reference timing. The lead angle is variably set according to the operating state of the motor 6. The on-timing is a timing at which the switch is switched from off to on by being set as the conducting pair; in other words, the on-timing is a start timing of the conduction angle. The reference timing may be a timing at which, for example, the edge transition occurs. Setting the lead angle according to the operating state and turning on the switch earlier than the reference timing makes it possible to effectively drive the motor 6.

In the lead angle control, the lead angle may be set such that, for example, the lead angle increases as the difference between the actual rotational speed ω_m and the speed command value ω_r increases.

FIG. 8 shows an example in which the lead angle control is not performed. In contrast, in the case where the lead angle control is performed, the on-timing of each of the first through sixth switches Q1 through Q6 becomes earlier than the on-timing shown in FIG. 8 (i.e., than the timing at which the edge transition occurs).

In such a second operation example as well, a square-wave voltage is applied to each of the first through third terminals 6a, 6b, and 6c of the motor 6. This causes the bus current to also vary periodically as schematically illustrated in FIG. 8.

### 2-1-4. Motor Control Process

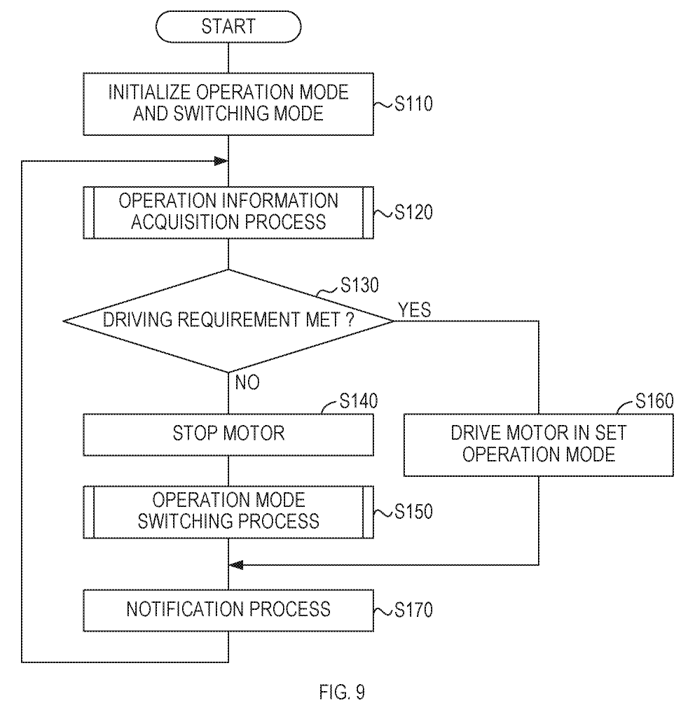

A description will be given, with reference to FIG. 9, as to a motor control process performed by the control circuit 30 (more specifically, by the processor 30a) to implement the above-described various functions. Upon being activated by receiving the power-supply voltage Vc, the control circuit 30 performs the motor control process.

Upon starting the motor control process, in S110, the control circuit 30 initializes the operation mode and the switching mode. Specifically, for example, the operation mode is set to the first mode, and the switching mode is set to the manual mode, as described above.

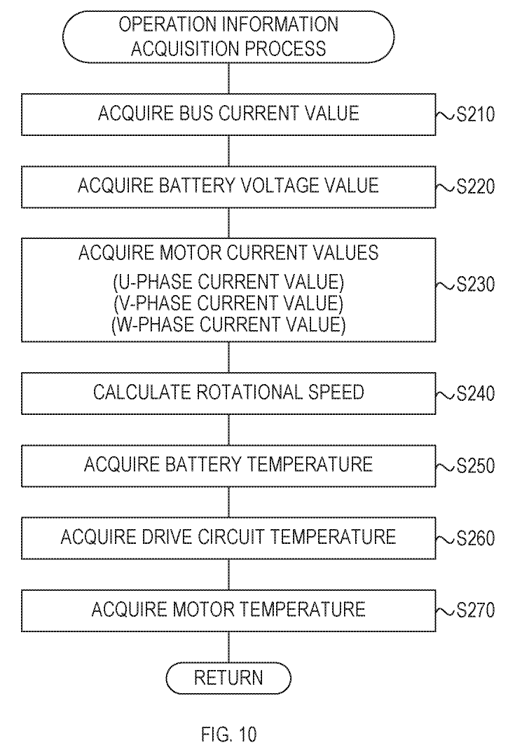

In S120, the control circuit 30 performs an operation information acquisition process. Details of the operation information acquisition process are shown in FIG. 10. Upon proceeding to the operation information acquisition process, in S210, the control circuit 30 acquires the bus current value based on the bus current detection signal Sib.

In S220, the control circuit 30 acquires the battery voltage value based on the battery voltage detection signal Svb.

In S230, the control circuit 30 acquires motor current values. Specifically, the control circuit 30 acquires the U-phase current value, the V-phase current value, and the W-phase current value based on the U-, V-, and W-phase current detection signals Siu, Siv, and Siw, respectively.

In S240, the control circuit 30 calculates the rotation angle θ and the actual rotational speed ω_m based on the first through third Hall signals Hu, Hv, and Hw.

In S250, the control circuit 30 acquires the battery temperature from the battery pack 15 through communication therewith. In S250, the control circuit 30 may acquire a part or all of the battery pack information Infb in addition to the battery temperature.

In S260, the control circuit 30 acquires the drive circuit temperature based on the first temperature detection signal Std.

In S270, the control circuit 30 acquires the motor temperature based on the second temperature detection signal Stm. After the process of S270, the present process proceeds to S130 (FIG. 9).

In S130, the control circuit 30 determines whether a driving requirement is met. The driving requirement is required to drive the motor 6. The driving requirement being met indicates being in a state in which the motor 6 should be driven. The driving requirement being not met indicates being in a state in which power supply to the motor 6 should be stopped to stop the motor 6.

The driving requirement may be set in any manner. In this first embodiment, the driving requirement is met based on (i) the trigger 10 being manually operated and (ii) driving of the motor 6 being not prohibited in the control circuit 30. The trigger 10 being manually operated may be rephrased as, for example, the first trigger signal TR1 indicating that the trigger 10 is manually operated. The control circuit 30 basically permits the driving of the motor 6. Thus, the control circuit 30 basically drives the motor 6 when the trigger 10 is manually operated. However, the control circuit 30 prohibits the driving of the motor 6 when detecting an abnormal state of the electric work machine 1.

If the driving requirement is met in S130, the present process proceeds to S160. In S160, the control circuit 30 drives the motor 6 according to the currently set operation mode. When the operation mode is set to the first mode, the control circuit 30 drives the motor 6 according to the first control scheme (specifically, the square-wave control). In the first mode, the above-described conduction angle control and/or lead angle control may be combined with the square-wave control. When the operation mode is set to the second mode, the control circuit 30 drives the motor 6 according to the second control scheme (specifically, FOC).

In S170, the control circuit 30 performs a notification process. Specifically, the control circuit 30 causes the indicator 12b to operate as described above, according to the currently set operation mode and switching mode. Specifically, for example, if the switching mode is set to the manual mode and the operation mode is set to the first mode, the control circuit 30 causes the indicator 12b to light up in the first manner. After the process of S170, the present process proceeds to S120.

If the driving requirement is not met in S130, the present process proceeds to S140. In S140, the control circuit 30 stops the motor 6. Specifically, the control circuit 30 turns off all of the first through sixth switches Q1 through Q6, thereby stopping the supply of the three-phase power to the motor 6.

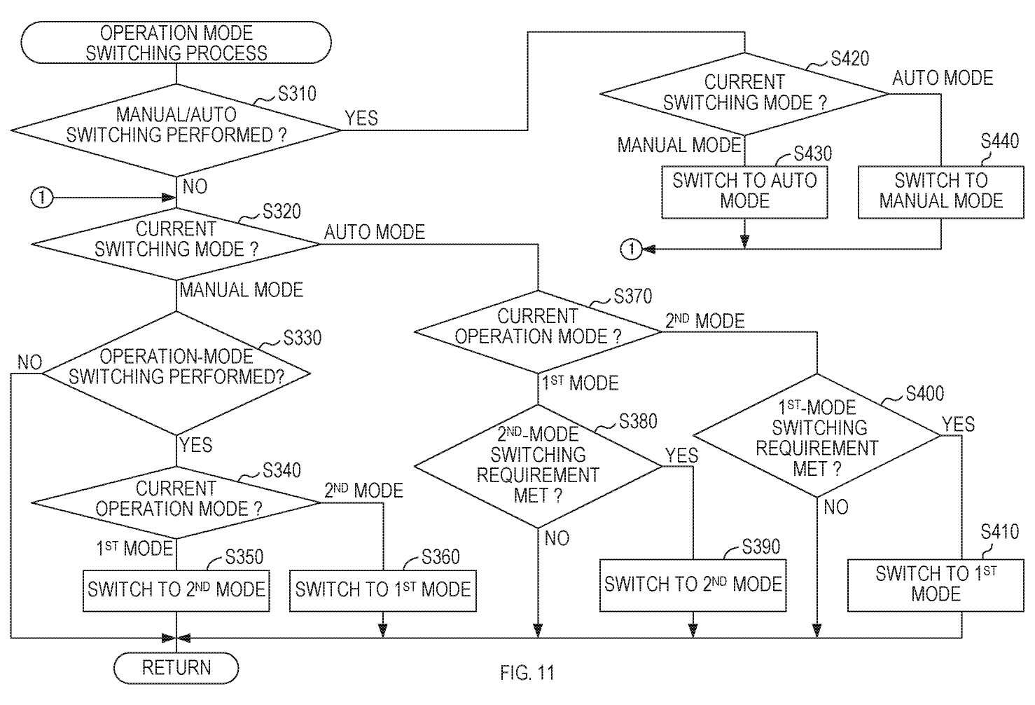

In S150, the control circuit 30 performs an operation mode switching process. Details of the operation mode switching process are shown in FIG. 11. Upon proceeding to the operation mode switching process, in S310, the control circuit 30 determines whether the manual/automatic switching operation has been performed on the mode setting switch 12a. If the manual/automatic switching operation has been performed, the present process proceeds to S420.

In S420, the control circuit 30 determines the currently set switching mode. If the currently set switching mode is the manual mode, in S430, the control circuit 30 switches the switching mode to the automatic mode. After the process of S430, the present process proceeds to S320. If the currently set switching mode is the automatic mode, in S440, the control circuit 30 switches the switching mode to the manual mode. After the process of S440, the present process proceeds to S320.

In S310, if the manual/automatic switching operation has not been performed, the present process proceeds to S320. In S320, the control circuit 30 determines the currently set switching mode. If the currently set switching mode is the manual mode, the present process proceeds to S330.

In S330, the control circuit 30 determines whether the operation-mode switching operation has been performed on the mode setting switch 12a. If the operation-mode switching operation has not been performed, the present process proceeds to S170 (FIG. 9). If the operation-mode switching operation has been performed, the present process proceeds to S340.

In S340, the control circuit 30 determines the currently set operation mode. If the currently set operation mode is the first mode, in S350, the control circuit 30 switches the operation mode to the second mode. After the process of S350, the present process proceeds to S170. If the currently set operation mode is the second mode, in S360, the control circuit 30 switches the operation mode to the first mode. After the process of S360, the present process proceeds to S170.

In S320, if the currently set switching mode is the automatic mode, the present process proceeds to S370. In S370, the control circuit 30 determines the currently set operation mode. If the currently set operation mode is the first mode, the present process proceeds to S380.

In S380, the control circuit 30 determines whether a second-mode switching requirement is met. The second-mode switching requirement is required to set the operation mode to the second mode. The second-mode switching requirement being met corresponds to a state in which the operation mode should be set (or may be set) to the second mode. Details of the second-mode switching requirement will be described below.

If the second-mode switching requirement is not met, the present process proceeds to S170.

If the second-mode switching requirement is met, the present process proceeds to S390. In S390, the control circuit 30 switched the operation mode to the second mode. After the process of S390, the present process proceeds to S170.

In S370, if the currently set operation mode is the second mode, the present process proceeds to S400. In S400, the control circuit 30 determines whether a first-mode switching requirement is met. The first-mode switching requirement is required to set the operation mode to the first mode. The first-mode switching requirement being met corresponds to a state in which the operation mode should be set (or may be set) to the first mode. Details of the first-mode switching requirement will be described below.

If the first-mode switching requirement is not met, the present process proceeds to S170.

If the first-mode switching requirement is met, the present process proceeds to S410. In S410, the control circuit 30 switches the operation mode to the first mode. After the process of S410, the present process proceeds to S170.

The first-mode switching requirement and the second-mode switching requirement will be described specifically.

The control circuit 30 may determine whether the first-mode switching requirement and the second-mode switching requirement are met based on the bus current detection signal Sib. Specifically, the second-mode switching requirement may be met based on the bus current value being equal to or greater than a first current threshold, and the first-mode switching requirement may be met based on the bus current value being equal to or less than a second current threshold. The second current threshold is less than the first current threshold and greater than zero.

Additionally or alternatively, the control circuit 30 may determine whether the first-mode switching requirement and the second-mode switching requirement are met based on the U-, V-, and W-phase current detection signals Siu, Siv, and Siw. Specifically, the second-mode switching requirement may be met based on a three-phase current level being equal to or higher than a third current threshold, and the first-mode switching requirement may be met based on the three-phase current level being equal to or lower than a fourth current threshold. The fourth current threshold is less than the third current threshold and greater than zero. The three-phase current level directly or indirectly indicates an amplitude of the three-phase currents. The three-phase current level may be, for example, a magnitude of the above-described current vector.

Additionally or alternatively, the control circuit 30 may determine whether the first-mode switching requirement and the second-mode switching requirement are met based on the battery voltage detection signal Svb. Specifically, the second-mode switching requirement may be met based on the battery voltage value being equal to or greater than a first voltage threshold, and the first-mode switching requirement may be met based on the battery voltage value being equal to or less than a second voltage threshold. The second voltage threshold is less than the first voltage threshold and greater than zero.

Additionally or alternatively, the control circuit 30 may determine whether the first-mode switching requirement and the second-mode switching requirement are met based on the first temperature detection signal Std. Specifically, the second-mode switching requirement may be met based on the drive circuit temperature being equal to or lower than a first temperature threshold, and the first-mode switching requirement may be met based on the drive circuit temperature being equal to or higher than a second temperature threshold. The first temperature threshold is less than the second temperature threshold and greater than zero.

Additionally or alternatively, the control circuit 30 may determine whether the first-mode switching requirement and the second-mode switching requirement are met based on the second temperature detection signal Stm. Specifically, the second-mode switching requirement may be met based on the motor temperature being equal to or lower than a third temperature threshold, and the first-mode switching requirement may be met based on the motor temperature being equal to or higher than a fourth temperature threshold. The third temperature threshold is less than the fourth temperature threshold and greater than zero.

Additionally or alternatively, the control circuit 30 may determine whether the first-mode switching requirement and the second-mode switching requirement are met based on the battery pack information Infb. Specifically, the second-mode switching requirement may be met based on the battery temperature being equal to or lower than a fifth temperature threshold, and the first-mode switching requirement may be met based on the battery temperature being equal to or higher than a sixth temperature threshold. The fifth temperature threshold is less than the sixth temperature threshold and greater than zero.

### 2-2. Second Embodiment

A description will be given of an electric work machine of the second embodiment. The electric work machine of this second embodiment differs from the electric work machine 1 of the first embodiment mainly in the following two points.

Specifically, in the first embodiment, the square-wave control is performed in the first mode, whereas in this second embodiment, first FOC is performed in the first mode. The first FOC includes the above-described field-weakening control.

Moreover, in this second embodiment, second FOC is performed in the second mode. The second FOC differs from the first FOC, and does not include the above-described field-weakening control. In other words, in the first embodiment, the MTPA control, the field-weakening control, or the zero d-axis current control is performed in the second mode, whereas in this second embodiment, the field-weakening control is not performed in the second mode.

Therefore, in this second embodiment, the control circuit 30 functions as shown in FIG. 4 in both the first mode and the second mode. That is, the control circuit 30 performs FOC in both the first and second modes. However, specific contents of FOC differ as described above.

Except for the above-described two points, the electric work machine of this second embodiment is configured basically in the same manner as the electric work machine 1 of the first embodiment.

That is, in this second embodiment as well, the motor control process shown in FIGS. 9-11 is performed. However, what is different from the motor control of the first embodiment is the process of S160. Specifically, in this second embodiment, in S160, if the operation mode is set to the first mode, the first FOC (i.e., the field-weakening control) is performed and, if the operation mode is set to the second mode, the second FOC (e.g., the MTPA control or the zero d-axis current control) is performed.

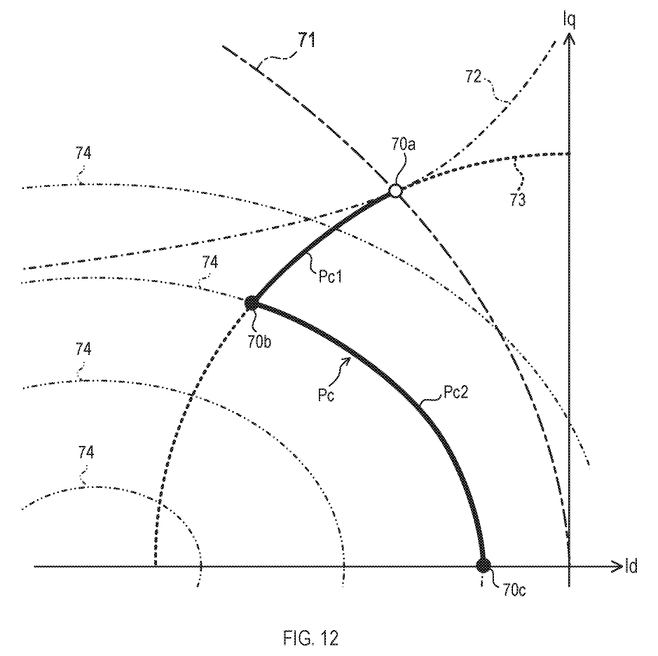

Examples of the current vector in the first FOC will be described with reference to FIGS. 12 and 13.

In the first FOC, for example, the current vector may be set to move along a part or a whole of a field-weakening trajectory Pc illustrated in FIG. 12. The field-weakening trajectory Pc includes a first trajectory Pc1 and a second trajectory Pc2. The first trajectory Pc1 extends from a first intersection 70a to a second intersection 70b, and does not include the first intersection 70a. The first intersection 70a is an intersection of the specific constant current circle 73 and the MTPA curve 71. The second intersection 70bis an intersection of the specific constant current circle 73 and the specific voltage limit ellipse 74. The second trajectory Pc2 extends from the second intersection 70b to a third intersection 70c, on the specific voltage limit ellipse 74. The third intersection 70c is an intersection of the specific voltage limit ellipse 74 and the d-axis.

Alternatively, for example, in a case where the motor 6 has a voltage limit ellipse 76 as illustrated in FIG. 13, in the first FOC, the current vector may move along a part or a whole of a field-weakening trajectory Pd illustrated in FIG. 13. In the example illustrated in FIG. 13, the center of the voltage limit ellipse 76 is included within the specific constant current circle 73.

The field-weakening trajectory Pd illustrated in FIG. 13 includes a first trajectory Pd1, a second trajectory Pd2, and a third trajectory Pd3. The first trajectory Pd1 extends from the first intersection 70a to a fourth intersection 70d, and does not include the first intersection 70a. The fourth intersection 70d is an intersection of the specific constant current circle 73 and the MTPV curve 75. The second trajectory Pd2 extends from the fourth intersection 70d to a fifth intersection 70e, on the MTPV curve 75. The fifth intersection 70e is an intersection of the MTPV curve 75 and the voltage limit ellipse 76. The third trajectory Pd3 extends from the fifth intersection 70e to a trajectory end point 70f, on the voltage limit ellipse 76. The trajectory end point 70f corresponds to an optional position, on the voltage limit ellipse 76, between the fifth intersection 70e and the d-axis. The trajectory end point 70f may be an intersection of the voltage limit ellipse 76 and the d-axis (provided that it is on a d-axis positive side relative to the MTPV curve 75).

In the second mode as well, the field-weakening control may be performed. In this case, however, the field-weakening control in the second mode may be set such that an amount of reduction in field flux is smaller than that in the field-weakening control in the first mode.

### 2-3. Third Embodiment

A description will be given of an electric work machine of the third embodiment. The electric work machine of this third embodiment differs from the electric work machine 1 of the first embodiment in the first control scheme in the first mode.

Specifically, the first control scheme in the first embodiment is the square-wave control, whereas the first control scheme in this third embodiment includes the first FOC. However, the first FOC in this third embodiment differs from that in the second embodiment.

In this third embodiment, in the second mode, FOC similar to that in the first embodiment is performed. For convenience of description, in this third embodiment, FOC performed in the second mode is referred to as the second FOC.

In this third embodiment, a main difference between the first FOC and the second FOC is that the first FOC includes the overmodulation control, whereas the second FOC does not include the overmodulation control. The first FOC may correspond to, for example, the second FOC to which further the overmodulation control is added. Specifically, for example, the second FOC may be the MTPA control, and the first FOC may correspond to the MTPA control to which further the overmodulation control is added. As another example, the first FOC may correspond to FOC, which is different from the second FOC, to which further the overmodulation control is added. Specifically, for example, the second FOC may be the MTPA control, and the first FOC may correspond to the field-weakening control (or a mixture of the MTPA control and the field-weakening control) to which further the overmodulation control is added.

The overmodulation control includes controlling the drive circuit 31 such that overmodulation voltage is applied from the drive circuit 31 to each of the first terminal 6a, the second terminal 6b, and the third terminal 6c. The overmodulation voltage includes a sinusoidal fundamental component. The overmodulation control further includes a period in which the overmodulation voltage is maintained at an upper limit value of the battery voltage value and a period in which the overmodulation voltage is maintained at zero voltage. That is, the overmodulation voltage varies along a reference sine wave Sref. The reference sine wave Sref has an amplitude greater than the battery voltage value. Furthermore, during a period in which the reference sine wave Sref is higher than the battery voltage value, the magnitude of the overmodulation voltage is maintained at the battery voltage value. “Varying along a reference sine wave Sref” as used herein is not limited to varying strictly along the reference sine wave Sref, but includes varying in a sinusoidal manner (i.e., along a trajectory similar to a sine wave as a whole). For example, the overmodulation voltage may include a basic sine wave component (i.e., a primary component) and one or more harmonic components (or components similar thereto).

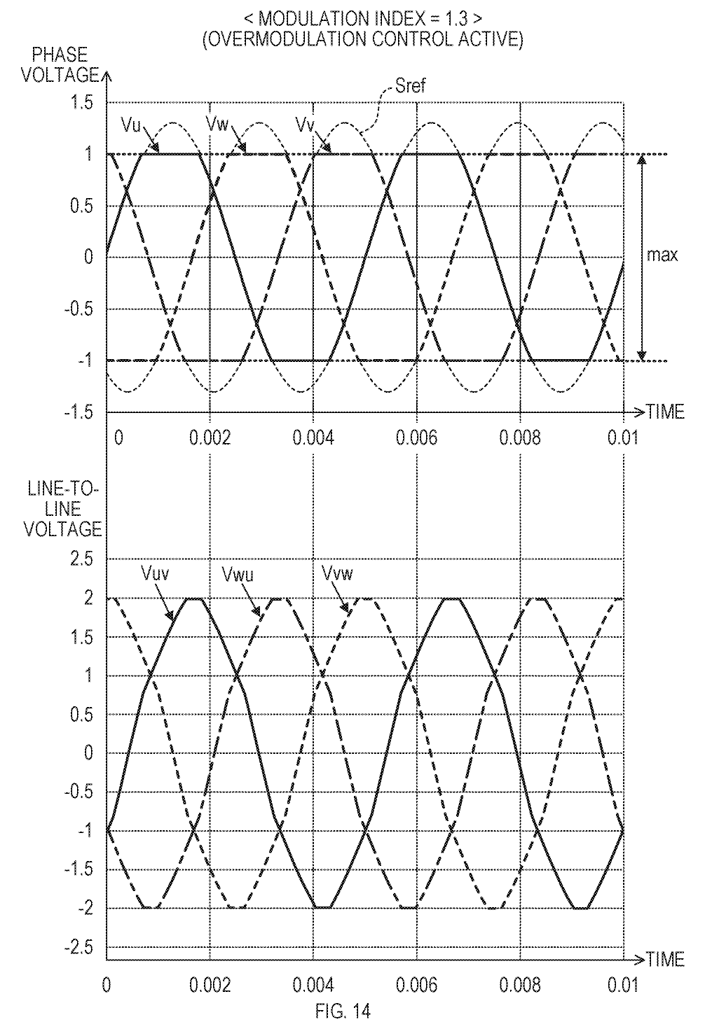

The upper part of FIG. 14 illustrates the overmodulation voltage when a modulation index (also referred to as a modulation factor) is 1.3. The modulation index is a ratio of the amplitude of the reference sine wave Sref to the battery voltage value. The modulation index being 1 corresponds to the amplitude of the reference sine wave Sref being equal to the battery voltage value. When the amplitude of the reference sine wave Sref exceeds the battery voltage value, the modulation index exceeds 1.

In FIG. 14, “max” indicates the battery voltage value. FIG. 14 shows a phase voltage and a line-to-line voltage. The vertical axis in FIG. 14 represents a ratio of each voltage when battery voltage is “1”. As is clear from FIG. 14, when the modulation index exceeds 1, the phase voltage is modulated according to the modulation index. This results in a slight distortion of the sinusoidal state in the line-to-line voltage as well.

In order to achieve the first FOC including such overmodulation control, the control circuit 30 basically functions as shown in FIG. 4 in the first mode, too. However, the functions partially differ from those shown in FIG. 4 in that the overmodulation control is performed.

Specifically, in the first FOC of this third embodiment, the voltage converter 47 acquires the battery voltage value from the battery voltage detection signal Svb. Further, in the control circuit 30, the modulation index has been set. The modulation index may be set manually by the user, or automatically according to the operating state of the electric work machine 1, or the like.

The voltage converter 47 generates the first through sixth drive signals UH, VH, WH, UL, VL, and WL based on the set modulation index and the battery voltage value. Specifically, the voltage converter 47 generates the first through sixth drive signals UH, VH, WH, UL, VL, and WL such that the overmodulation voltage according to the set modulation index is applied to each of the first through third terminals 6a, 6b, and 6c.

### 2-4. Fourth Embodiment

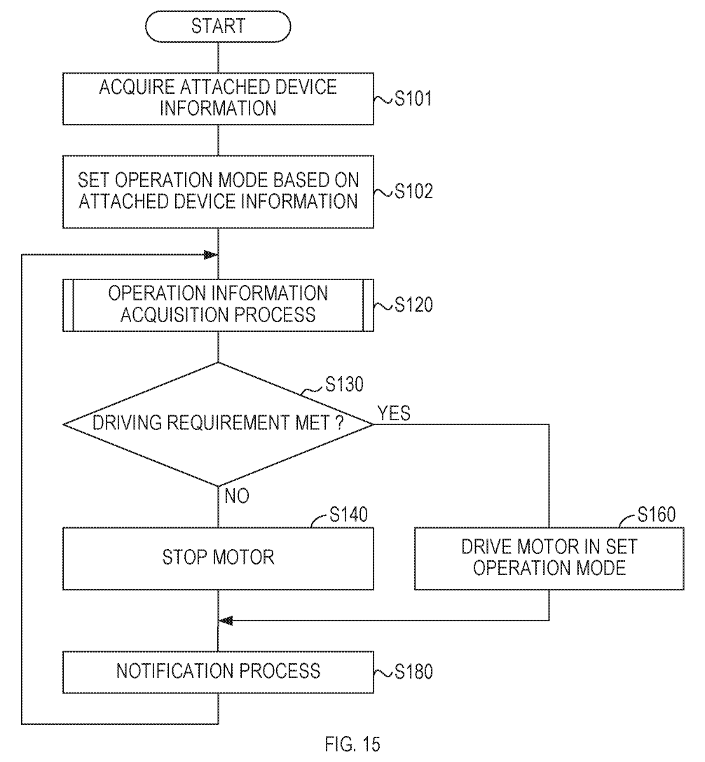

Another example of the motor control process of the first embodiment (FIG. 9) will be described as the fourth embodiment. In the motor control process of this fourth embodiment shown in FIG. 15, the processes of S101 and S102 are added instead of the process of S110 as compared with the motor control process of the first embodiment. Furthermore, the process of S150 of the first embodiment is omitted. In FIG. 15, the same processes as those in FIG. 9 are denoted by the same numerals as those in FIG. 9. Hereinafter, the motor control process shown in FIG. 15 will be described, focusing mainly on points different from that shown in FIG. 9.

In this fourth embodiment, the switching mode is not set. In other words, the user cannot manually switch the operation mode, and the operation mode is basically set automatically. However, in this fourth embodiment as well, the operation mode may be able to be set manually. Specifically, the user may be able to manually change the operation mode set in S102, which will be described below.

Upon starting the motor control process in FIG. 15, in S101, the control circuit 30 acquires attached device information. The attached device information includes the above-described battery pack information Infb, and/or tool information Sto.

In S102, the control circuit 30 sets the operation mode to the first mode or the second mode based on the attached device information acquired in S101. Specifically, the control circuit 30 sets the operation mode to the first mode based on the attached device information meeting a first setting requirement, and sets the operation mode to the second mode based on the attached device information meeting a second setting requirement.

The first and second setting requirements may be determined as appropriate. For example, the attached device information may include a magnitude of internal resistance of the battery 15a. In this case, the first and second setting requirements may be set based on the magnitude of the internal resistance. Specifically, the first setting requirement may be met based on the magnitude of the internal resistance being equal to or greater than a first threshold. The second setting requirement may be met based on the magnitude of the internal resistance being equal to or less than a second threshold. The second threshold is less than the first threshold and greater than zero. That is, in this case, the control circuit 30 may set the operation mode to the first mode if the magnitude of the internal resistance is equal to or greater than the first threshold, and may set the operation mode to the second mode if the magnitude of the internal resistance is equal to or less than the second threshold.

As another example, the attached device information may include the model information of the battery pack 15. In this case, the first and second setting requirements may be set based on a model indicated by the model information. Specifically, the control circuit 30 may have model-mode correspondence information in which multiple types of models are each associated with the first mode or the second mode. In this case, the first setting requirement may be met based on the acquired model being associated with the first mode in the model-mode correspondence information. The second setting requirement may be met based on the acquired model being associated with the second mode in the model-mode correspondence information.

As another example, the attached device information may include the tool information Sto. In this case, the first and second setting requirements may be set based on a type of the end tool 9 indicated by the tool information Sto. Specifically, the first setting requirement may be met based on the end tool 9 being classified as the above-described first-type tool. The second setting requirement may be met based on the end tool 9 being classified as the above-described second-type tool.

The processes of S120, S130, S140, and S160 are similar to those in the first embodiment. In this fourth embodiment, after each process of S140 and S160, the present process proceeds to S180.

In S180, the control circuit 30 performs the notification process. Specifically, the control circuit 30 causes the indicator 12b to light up in the first manner when the operation mode is set to the first mode, and causes the indicator 12b to light up in the second manner when the operation mode is set to the second mode.

### 2-5. Fifth Embodiment

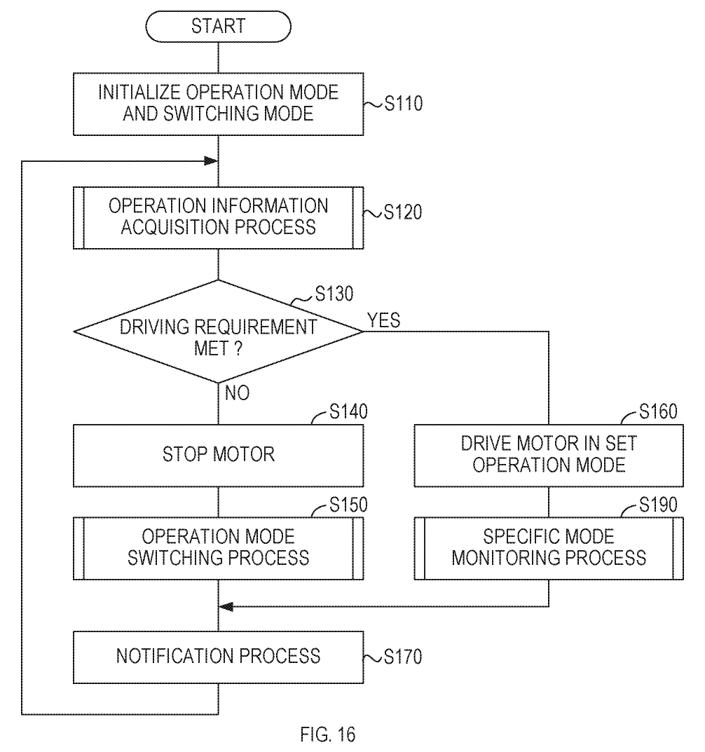

Still another example of the motor control process of the first embodiment (FIG. 9) will be described as the fifth embodiment. The motor control process of this fifth embodiment shown in FIG. 16 differs from that of the first embodiment in that the process of S190 is added after S160.

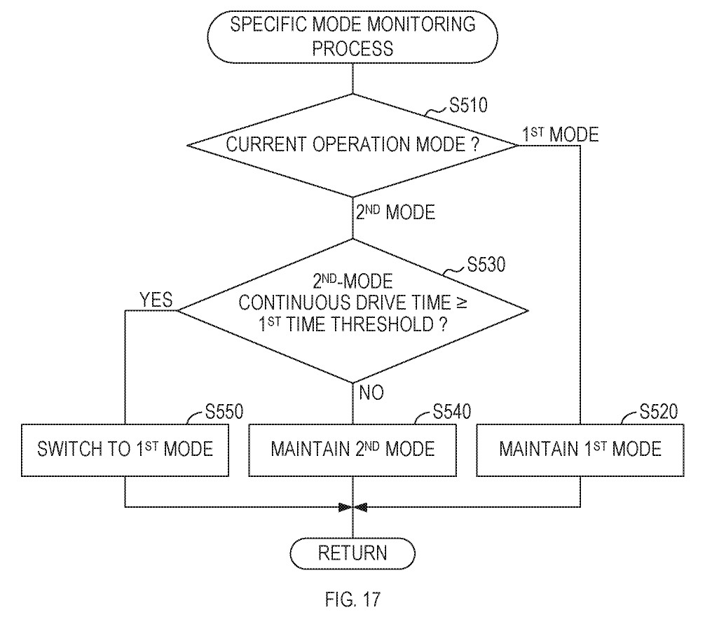

In S190, the control circuit 30 performs a specific mode monitoring process. Details of the specific mode monitoring process are as shown in FIG. 17.

Upon proceeding to the specific mode monitoring process, in S510, the control circuit 30 determines (or acquires) the currently set operation mode. If the currently set operation mode is the first mode, in S520, the control circuit 30 maintains the operation mode in the first mode. After the process of S520, the present process proceeds to S170 (FIG. 16). If the currently set operation mode is the second mode, the present process proceeds to S530.

In S530, the control circuit 30 determines whether a second-mode continuous drive time is equal to or longer than a first time threshold. The second-mode continuous drive time refers to a time during which the motor 6 is continuously driven in the second mode. The second-mode continuous drive time may be rephrased as a time during which the trigger 10 is continuously pressed in the second mode (thereby continuously driving the motor 6).

If the second-mode continuous drive time has not reached the first time threshold, the present process proceeds to S540. In S540, the control circuit 30 maintains the operation mode in the second mode. After the process of S540, the present process proceeds to S170.

In S530, if the second-mode continuous drive time has reached the first time threshold, the present process proceeds to S550. In S550, the control circuit 30 switches the operation mode to the first mode. After the process of S550, the present process proceeds to S170.

As described above, the second mode is an operation mode in which priority is given to output torque. Thus, if the second-mode continuous drive time exceeds the first time threshold, the drive circuit temperature, the motor temperature, and/or the battery temperature increase/increases, which may affect operations and reliability of the drive circuit 31, the motor 6, and/or the battery 15a, respectively. For this reason, the control circuit 30 forcibly switches the operation mode to the first mode when the second-mode continuous drive time becomes long. This results in protecting the drive circuit 31, the motor 6, and/or the battery 15a from overheating.

### 2-6. Sixth Embodiment

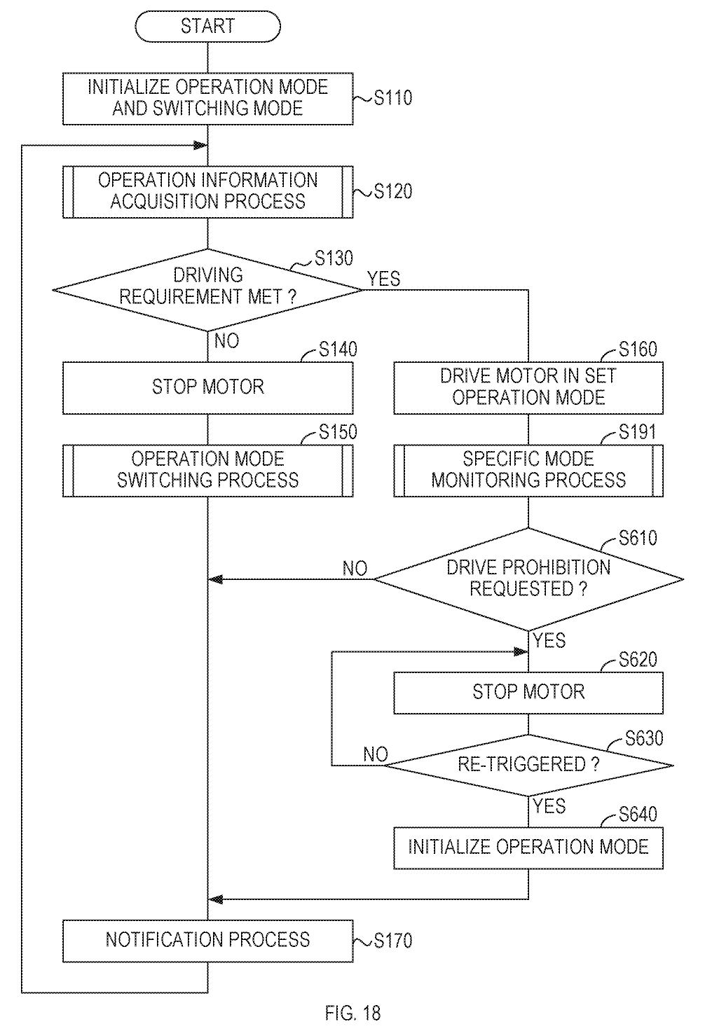

Yet another example of the motor control process of the first embodiment (FIG. 9) will be described as the sixth embodiment. The motor control process of this sixth embodiment shown in FIG. 18 differs from that of the fifth embodiment (FIG. 16) in that the process of S191 is performed instead of the process of S190, and in that the processes of S610 through S640 are added after the process of S191.

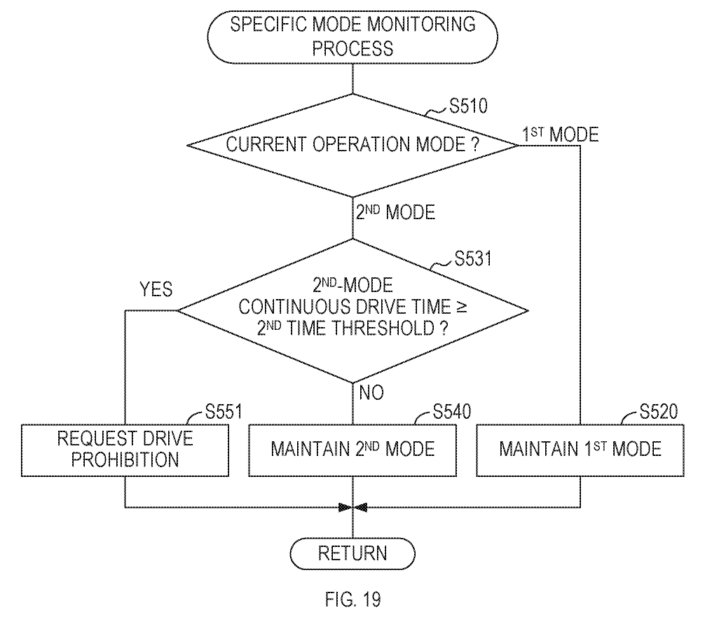

In S191, the control circuit 30 performs a specific mode monitoring process. This specific mode monitoring process is partially different from that performed in S190 in the fifth embodiment. Details of the specific mode monitoring process of S191 are as shown in FIG. 19.

The specific mode monitoring process shown in FIG. 19 differs from that shown in FIG. 17 in that the process of S531 is performed instead of that of S530, and in that the process of S551 is performed instead of the process of S550.

In S531, the control circuit 30 determines whether the second-mode continuous drive time is equal to or longer than a second time threshold. The second time threshold may be the same as or different from the first time threshold of the fifth embodiment.

If the second-mode continuous drive time has not reached the second time threshold, the present process proceeds to S540. If the second-mode continuous drive time has reached the second time threshold, the present process proceeds to S551.

In S551, the control circuit 30 sets a drive prohibition request flag. After the process of S551, the present process proceeds to S610 (FIG. 18).

In S610, the control circuit 30 determines whether the drive prohibition request flag is set. If the drive prohibition request flag is not set, the present process proceeds to S170. If the drive prohibition request flag is set, the present process proceeds to S620.

In S620, the control circuit 30 stops the motor 6. Specifically, the control circuit 30 turns off all of the first through sixth switches Q1 through Q6, thereby stopping the supply of the three-phase power to the motor 6.

In S630, the control circuit 30 determines whether re-triggering has been performed by the user. Re-triggering refers to temporarily releasing the manual operation of the trigger 10 and then manually operating the trigger 10 again. If re-triggering has not been performed (i.e., if the manual operation of the trigger 10 is maintained), the present process proceeds to S620. That is, in this case, the stoppage of the motor 6 is continued. In contrast, if re-triggering has been performed, the present process proceeds to S640.

In S640, the control circuit 30 initializes the operation mode. Specifically, the control circuit 30 may initialize the operation mode in the same manner as in S110. After the process of S640, the present process proceeds to S170.

### 3. Other Embodiments

Although the embodiments of the present disclosure have been described so far, the present disclosure is not limited to the above-described embodiments and can be implemented with various modifications.

(3-1) In the automatic mode, the control circuit 30 may switch the operation mode based on any determination criteria.

For example, the second-mode switching requirement may be met on the basis that the load torque applied to the motor 6 via the end tool 9 is equal to or higher than a first torque threshold. The first-mode switching requirement may be met on the basis that the load torque is equal to or lower than a second torque threshold. In this case, the second torque threshold is less than the first torque threshold and greater than zero.

The control circuit 30 may acquire the load torque in any manner. The electric work machine 1 may include, for example, a torque sensor that detects the load torque. The torque sensor may be provided in the power transmission portion 7, for example. The torque sensor may be configured to output a torque signal. The torque signal may correspond to a magnitude of a mechanical torsion occurring in the power transmission portion 7 due to the load torque. The control circuit 30 may acquire the load torque based on the torque signal from the torque sensor. Alternatively, the control circuit 30 may detect (or estimate) the load torque from the operating state of the motor 6. For example, the control circuit 30 may detect the load torque based on the bus current value.

(3-2) The electric work machine may have only the automatic mode or only the manual mode. That is, the electric work machine does not necessarily have to have a function for setting the switching mode.

(3-3) The motor 6 may be controlled according to a so-called sensorless scheme. That is, the electric work machine 1 does not necessarily have to include the position signal output circuit 21. In this case, the control circuit 30 may calculate the rotation angle θ and the actual rotational speed ω_m based on a back-EMF generated at the first through third terminals 6a, 6b, and 6c of the motor 6.

(3-4) Two or more functions implemented by a single element in the above-described embodiments may be implemented by two or more elements, and a single function implemented by a single element may be implemented by two or more elements. Two or more functions implemented by two or more elements may be implemented by a single element, and a single function implemented by two or more elements may be implemented by a single element. A portion of the configurations in the above-described embodiments may be omitted. At least a portion of the configuration in one of the above-described embodiments may be added to or replace the configuration in another one of the above-described embodiments.

What is claimed is:

1. An electric work machine comprising:
a brushless motor configured to drive an end tool;
a drive circuit configured to (i) receive a DC power from a DC power supply, (ii) generate three-phase power from the DC power received, and (iii) supply the three-phase power generated to the brushless motor to drive the brushless motor; and
a control circuit configured to:
selectively set an operation mode of the control circuit to one of a first mode and a second mode;
control the brushless motor through the drive circuit according to a first control scheme, based on the operation mode being set to the first mode, the first control scheme (i) being a control scheme other than field-oriented control or (ii) including a first field-oriented control; and
control the brushless motor through the drive circuit according to a second control scheme, based on the operation mode being set to the second mode, the second control scheme (i) being different from the first control scheme and (ii) including a second field-oriented control different from the first field-oriented control.

2. The electric work machine according to claim 1, wherein
the first control scheme (i) is the control scheme other than the field-oriented control and (ii) includes square-wave control.

3. The electric work machine according to claim 2, wherein
the drive circuit includes a three-phase bridge circuit having six switches,
the first control scheme includes:
turning on each of the six switches continuously or intermittently during a period from a corresponding on-timing until the brushless motor rotates by an angle corresponding to a conduction angle; and
lead angle control and/or conduction angle control,
the lead angle control includes (i) advancing the on-timing of each of the six switches by a time corresponding to a lead angle from a reference timing and (ii) varying the lead angle according to an operating state of the brushless motor, and
the conduction angle control includes varying the conduction angle according to an operating state of the brushless motor.

4. The electric work machine according to claim 1, wherein
the brushless motor includes a first terminal, a second terminal, and a third terminal configured to receive, from the drive circuit, respective three-phase currents corresponding to the three-phase power,
the first control scheme includes the first field-oriented control,
the second field-oriented control includes supplying the three-phase currents to the brushless motor such that a current vector of the three-phase currents moves along a maximum torque per ampere curve of the brushless motor in a d-q reference frame,
the d-q reference frame has a d-axis and a q-axis orthogonal to each other, and
the current vector is a vector sum of a d-axis current and a q-axis current, the d-axis current corresponds to a d-axis component in the three-phase currents, and the q-axis current corresponds to a q-axis component in the three-phase currents.

5. The electric work machine according to claim 4, wherein
the first field-oriented control includes field-weakening control, the field-weakening control including supplying the three-phase currents to the brushless motor such that the current vector moves within a first region in the d-q reference frame, and
the first region corresponds to a region (i) not including the maximum torque per ampere curve and (ii) on a d-axis negative side relative to the maximum torque per ampere curve.

6. The electric work machine according to claim 4, wherein
the first field-oriented control includes applying an overmodulation voltage from the drive circuit to each of the first terminal, the second terminal, and the third terminal,
a magnitude of the overmodulation voltage (i) varies along a reference sine wave, the reference sine wave having an amplitude greater than a magnitude of a DC voltage, the DC voltage being applied from the DC power supply to the drive circuit, and (ii) is maintained at a magnitude of the DC voltage in a period in which a magnitude of the reference sine wave is greater than the magnitude of the DC voltage.

7. The electric work machine according to claim 1, further comprising:
a manual switch configured to allow a user of the electric work machine to perform a first manual operation and a second manual operation,
wherein the control circuit is configured to:
set the operation mode to the first mode based on the first manual operation being performed on the manual switch; and
set the operation mode to the second mode based on the second manual operation being performed on the manual switch.

8. The electric work machine according to claim 1, wherein
the control circuit is configured to:
switch the operation mode to the first mode based on (i) the operation mode being set to the second mode and (ii) a first-mode switching requirement being met, and/or
switch the operation mode to the second mode based on (i) the operation mode being set to the first mode and (ii) a second-mode switching requirement being met.

9. The electric work machine according to claim 8, wherein
the second-mode switching requirement is met based on a load torque being equal to or higher than a first torque threshold, the load torque being a torque applied to the brushless motor via the end tool,
the first-mode switching requirement is met based on the load torque being equal to or lower than a second torque threshold, and
the second torque threshold is less than the first torque threshold and greater than zero.

10. The electric work machine according to claim 8, wherein
the second-mode switching requirement is met based on a magnitude of a bus current being equal to or greater than a first current threshold, the bus current being a current supplied from the DC power supply to the brushless motor through the drive circuit,
the first-mode switching requirement is met based on the magnitude of the bus current being equal to or less than a second current threshold, and
the second current threshold is less than the first current threshold and greater than zero.

11. The electric work machine according to claim 8, wherein
the brushless motor includes a first terminal, a second terminal, and a third terminal configured to receive, from the drive circuit, respective three-phase currents corresponding to the three-phase power,
the second-mode switching requirement is met based on a current level being equal to or higher than a third current threshold, the current level indicating an amplitude of the three-phase currents directly or indirectly,
the first-mode switching requirement is met based on the current level being equal to or lower than a fourth current threshold, and
the fourth current threshold is less than the third current threshold and greater than zero.

12. The electric work machine according to claim 8, wherein
the drive circuit is configured to receive a DC voltage corresponding to the DC power from the DC power supply,
the second-mode switching requirement is met based on a magnitude of the DC voltage being equal to or greater than a first voltage threshold,
the first-mode switching requirement is met based on the magnitude of the DC voltage being equal to or less than a second voltage threshold, and
the second voltage threshold is less than the first voltage threshold and greater than zero.

13. The electric work machine according to claim 8, wherein
the second-mode switching requirement is met based on a temperature of the drive circuit being equal to or lower than a first temperature threshold,
the first-mode switching requirement is met based on the temperature of the drive circuit being equal to or higher than a second temperature threshold, and
the first temperature threshold is less than the second temperature threshold and greater than zero.

14. The electric work machine according to claim 8, wherein
the second-mode switching requirement is met based on a temperature of the brushless motor being equal to or lower than a third temperature threshold,
the first-mode switching requirement is met based on the temperature of the brushless motor being equal to or higher than a fourth temperature threshold, and
the third temperature threshold is less than the fourth temperature threshold and greater than zero.

15. The electric work machine according to claim 8, wherein
the DC power supply includes a battery,
the second-mode switching requirement is met based on a temperature of the battery being equal to or lower than a fifth temperature threshold,
the first-mode switching requirement is met based on the temperature of the battery being equal to or higher than a sixth temperature threshold, and
the fifth temperature threshold is less than the sixth temperature threshold and greater than zero.

16. The electric work machine according to claim 7, wherein
the control circuit is configured to switch the operation mode to the first mode in response to (i) the operation mode being set to the second mode and (ii) the brushless motor having been continuously controlled according to the second control scheme for a first threshold time or longer.

17. The electric work machine according to claim 7, wherein
the control circuit is configured to stop supply of the three-phase power from the drive circuit to the brushless motor in response to (i) the operation mode being set to the second mode and (ii) the brushless motor having been continuously controlled according to the second control scheme for a second threshold time or longer.

18. The electric work machine according to claim 1, wherein
the control circuit is configured to:
acquire attached device information regarding an attached device attached to the electric work machine,
set the operation mode to the first mode based on the attached device information meeting a first setting requirement, and
set the operation mode to the second mode based on the attached device information meeting a second setting requirement.

19. The electric work machine according to claim 18, wherein
the DC power supply includes a battery,
the electric work machine includes a battery port configured to allow a battery pack to be detachably attached thereto, the battery pack housing the battery,
the control circuit is configured to acquire battery information from the battery pack attached to the battery port, the battery information indicating performance of the battery directly or indirectly, and
the attached device information includes the battery information.

20. The electric work machine according to claim 19, wherein
the battery has internal resistance,
the battery information includes a magnitude of the internal resistance,
the first setting requirement is met based on the magnitude of the internal resistance being equal to or greater than a first threshold,
the second setting requirement is met based on the magnitude of the internal resistance being equal to or less than a second threshold, and
the second threshold is less than the first threshold and greater than zero.

21. The electric work machine according to claim 18, wherein
the DC power supply includes a battery,
the electric work machine includes a battery port configured to allow a battery pack to be detachably attached thereto, the battery pack housing the battery,
the control circuit is configured to acquire model information from the battery pack attached to the battery port, the model information indicating a model of the battery pack, and
the attached device information includes the model information.

22. The electric work machine according to claim 18, wherein
the control circuit is configured to acquire tool information, the tool information indicating a type of the end tool attached to the electric work machine, and
the attached device information includes the tool information.

23. The electric work machine according to claim 1, wherein
a maximum value of a rotational speed of the brushless motor in the first mode is greater than a maximum value of the rotational speed in the second mode, and/or
a maximum value of an output torque of the brushless motor in the second mode is greater than a maximum value of the output torque in the first mode.

24. A method for controlling a brushless motor in an electric work machine, the method comprising:
selectively setting an operation mode of the electric work machine equipped with the brushless motor to one of a first mode and a second mode;
controlling driving of the brushless motor according to a control scheme other than field-oriented control or by a first field-oriented control while the operation mode is set to the first mode; and
controlling the driving of the brushless motor by a second field-oriented control while the operation mode is set to the second mode, the first field-oriented control being different from the second field-oriented control.
